(19) United States
(12) Patent Application Publication
(10) Pub. No.: US 2026/0333924 A1
(43) Pub. Date: Oct. 22, 2026

(54) IMAGING ELEMENT AND ELECTRONIC DEVICE

(71) Applicant: SONY SEMICONDUCTOR SOLUTIONS CORPORATION, KANAGAWA (JP)

(72) Inventors: YOSHIAKI MASUDA, KANAGAWA (JP); KEISUKE HATANO, KANAGAWA (JP); KENGO NAGATA, KANAGAWA (JP); SHINICHIRO NOUDO, KANAGAWA (JP); TAKAHISA FURUHASHI, KANAGAWA (JP); ATSUHIRO ANDO, KANAGAWA (JP)

(21) Appl. No.: 19/114,809

(22) PCT Filed: Sep. 28, 2023
(86) PCT No.: PCT/JP2023/035436

§ 371 Date: Mar. 25, 2025

(30) Foreign Application Priority Data
Sep. 30, 2022 (JP) 2022-157594

(51) Int. Cl. H10F 39/00

(52) U.S. Cl. CPC H10F 39/811; H10F 39/806

(57) ABSTRACT

The present technology relates to an imaging element and an electronic device that make it possible to reduce time and effort required for inspection performed at the time of manufacturing. Included are: a pixel array unit in which pixels each including a photoelectric conversion element are two-dimensionally arranged; a pad including an opening on a side of a first surface on which the pixel array unit is provided; an electrode provided in a state of being exposed to the bottom of the pad; a through electrode including an opening on a second surface on an opposite side from the first surface; and a rewiring layer stacked on the second surface, and the inside of the through electrode is a cavity. The present technology can be applied to, for example, a wafer-level chip size package (WLCSP) imaging element.

### TECHNICAL FIELD

The present technology relates to an imaging element and an electronic device, and, for example, relates to an imaging element and an electronic device that can be downsized.

### BACKGROUND ART

Conventionally, there has been proposed an imaging element in which a transparent adhesive is applied to an entire light receiving region and peripheral circuit region of a light receiving surface to place and fix a transparent member (see Patent Documents 1 to 3).

### CITATION LIST

### Patent Document

Patent Document 1: Japanese Patent Application Laid-Open No. 2004-207461

Patent Document 2: Japanese Patent Application Laid-Open No. 2008-270650

Patent Document 3: Japanese Patent Application Laid-Open No. 2012-175461

### SUMMARY OF THE INVENTION

### Problems to be Solved by the Invention

There is a demand for further reduction in height (downsizing) of imaging elements, and the above-described conventional imaging element has had room for contrivance for thinning each part. Furthermore, for example, in a case where inspection of characteristics of an imaging element is performed at the time of manufacturing, it is desired to reduce time and effort required for the inspection.

The present technology has been made in view of such a situation, and makes it possible to further downsize an imaging element and/or reduce time and effort required for inspection.

### Solutions to Problems

A first imaging element according to one aspect of the present technology is an imaging element including: a pixel array unit in which pixels each including a photoelectric conversion element are two-dimensionally arranged; a pad including an opening on a side of a first surface on which the pixel array unit is provided; an electrode provided in a state of being exposed to the bottom of the pad; a through electrode including an opening on a second surface on an opposite side from the first surface; and a rewiring layer stacked on the second surface, in which the inside of the through electrode is a cavity.

A second imaging element according to one aspect of the present technology is an imaging element including: a pixel array unit in which pixels each including a photoelectric conversion element are two-dimensionally arranged; a wiring line connected to a circuit that processes a signal from the pixel array unit and exposed on a side surface of the imaging element; and a fuse provided on a part of the wiring line.

An electronic device according to one aspect of the present technology is an electronic device including: an imaging element including: a pixel array unit in which pixels each including a photoelectric conversion element are two-dimensionally arranged; a pad including an opening on a side of a first surface on which the pixel array unit is provided; an electrode provided in a state of being exposed to the bottom of the pad; a through electrode including an opening on a second surface on an opposite side from the first surface; and a rewiring layer stacked on the second surface, in which the inside of the through electrode is a cavity; and a processing unit that processes a signal from the imaging element.

In the first imaging element according to one aspect of the present technology, included are: the pixel array unit in which the pixels each including the photoelectric conversion element are two-dimensionally arranged; the pad including the opening on the first surface side on which the pixel array unit is provided; the electrode provided in the state of being exposed to the bottom of the pad; the through electrode including the opening on the second surface on the opposite side from the first surface; and the rewiring layer stacked on the second surface, and the inside of the through electrode is the cavity.

In the second imaging element according to one aspect of the present technology, included are: the pixel array unit in which the pixels each including the photoelectric conversion element are two-dimensionally arranged; the wiring line connected to the circuit that processes the signal from the pixel array unit and exposed on the side surface of the imaging element; and the fuse provided on the part of the wiring line.

In the electronic device according to one aspect of the present technology, the first imaging element is included.

Note that the electronic device may be an independent device, or may be an internal block constituting one device.

### BRIEF DESCRIPTION OF DRAWINGS

FIG. 1 is a diagram illustrating a configuration according to an embodiment of an imaging element to which the present technology is applied.

FIG. 2 is a diagram illustrating a circuit configuration example of a pixel.

FIG. 3 is a diagram for explaining arrangement of pads.

FIG. 4 is a diagram illustrating a configuration example of an imaging element according to a first embodiment.

FIG. 5 is a diagram illustrating a configuration example of an imaging element according to a second embodiment.

FIG. 6 is a diagram for explaining a positional relationship between a pad and a through electrode.

FIG. 7 is a diagram for explaining a positional relationship between pads and through electrodes.

FIG. 8 is a diagram for explaining manufacturing of the imaging element.

FIG. 9 is a diagram illustrating a configuration example of an imaging element according to a third embodiment.

FIG. 10 is a diagram illustrating a configuration example of the imaging element according to the third embodiment.

FIG. 11 is a diagram illustrating a configuration example of an imaging element according to a fourth embodiment.

FIG. 12 is a diagram for explaining a distance between the pad and a through electrode 76.

FIG. 13 is a diagram illustrating a configuration example of the imaging element according to the fourth embodiment.

FIG. 14 is a diagram illustrating a configuration example of an imaging element according to a fifth embodiment.

FIG. 15 is a diagram illustrating a configuration example of an imaging element according to a sixth embodiment.

FIG. 16 is a diagram for explaining reflected light in an electrode.

FIG. 17 is a diagram illustrating a configuration example of a pad according to a seventh embodiment.

FIG. 18 is a diagram illustrating a configuration example of a pad according to an eighth embodiment.

FIG. 19 is a diagram illustrating a configuration example of an imaging element according to the eighth embodiment.

FIG. 20 is a diagram illustrating a configuration example of an imaging element according to a ninth embodiment.

FIG. 21 is a diagram illustrating a configuration example of an imaging element according to a tenth embodiment.

FIG. 22 is a diagram illustrating a planar configuration example of an imaging element according to an eleventh embodiment.

FIG. 23 is a diagram illustrating a cross-sectional configuration example of the imaging element according to the eleventh embodiment.

FIG. 24 is a diagram illustrating another configuration example of the imaging element according to the eleventh embodiment.

FIG. 25 is a diagram for explaining a position of a needle at the time of inspection of the imaging element.

FIG. 26 is a diagram illustrating another planar configuration example of the imaging element according to the eleventh embodiment.

FIG. 27 is a diagram illustrating another cross-sectional configuration example of the imaging element according to the eleventh embodiment.

FIG. 28 is a diagram for explaining manufacturing of the imaging element.

FIG. 29 is a diagram for explaining the manufacturing of the imaging element.

FIG. 30 is a diagram illustrating a configuration example of lead-out wiring lines in the eleventh embodiment.

FIG. 31 is a diagram illustrating a configuration example of the lead-out wiring lines in the eleventh embodiment.

FIG. 32 is a diagram illustrating another planar configuration example of the imaging element according to the eleventh embodiment.

FIG. 33 is a diagram illustrating another cross-sectional configuration example of the imaging element according to the eleventh embodiment.

FIG. 34 is a diagram illustrating a configuration example of an imaging element according to a twelfth embodiment.

FIG. 35 is a diagram for explaining positions of dicing lines.

FIG. 36 is a diagram for explaining the positions of the dicing lines.

FIG. 37 is a diagram illustrating another cross-sectional configuration example of the imaging element according to the twelfth embodiment.

FIG. 38 is a diagram illustrating another planar configuration example of the imaging element according to the twelfth embodiment.

FIG. 39 is a diagram illustrating a configuration example of an electronic device.

FIG. 40 is a diagram depicting an example of a schematic configuration of an endoscopic surgery system.

FIG. 41 is a block diagram depicting an example of functional configurations of a camera head and a CCU.

FIG. 42 is a block diagram illustrating an example of a schematic configuration of a vehicle control system.

FIG. 43 is an explanatory diagram illustrating an example of installation positions of an outside-vehicle information detecting section and an imaging section.

### MODE FOR CARRYING OUT THE INVENTION

Hereinafter, a mode for carrying out the present technology (hereinafter referred to as an embodiment) will be described.

### Schematic Configuration Example of Imaging Element

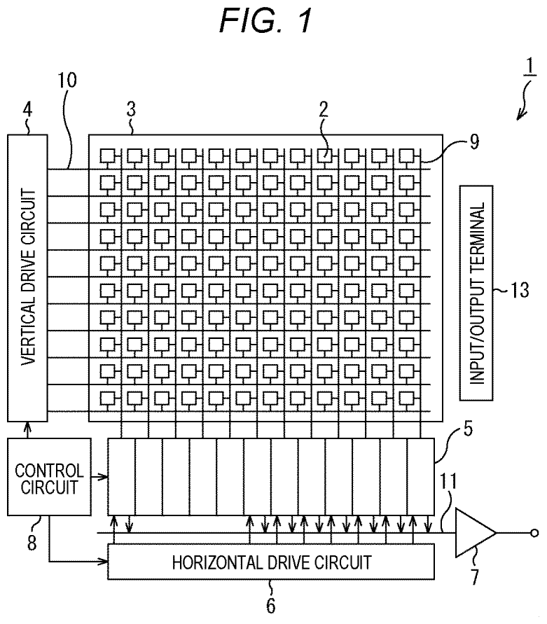

FIG. 1 illustrates a schematic configuration example of an example of a complementary metal oxide semiconductor (CMOS) imaging element applied to an embodiment of the present technology.

As illustrated in FIG. 1, an imaging element (element chip) 1 includes a pixel array unit 3 (pixel region, so-called imaging region) in which a plurality of pixels 2 each including a photoelectric conversion element is regularly and two-dimensionally arranged on a semiconductor substrate 11 (for example, a silicon substrate), and a peripheral circuit region.

Each pixel 2 includes the photoelectric conversion element (for example, a photo diode (PD) ) and a plurality of pixel transistors (so-called MOS transistors). The plurality of pixel transistors can include, for example, three transistors of a transfer transistor, a reset transistor, and an amplification transistor, and further can include four transistors by addition of a selection transistor.

Furthermore, the pixels 2 may also have a pixel sharing structure. The pixel sharing structure includes a plurality of photodiodes, a plurality of transfer transistors, one shared floating diffusion, and one each of shared other pixel transistors. Each photodiode is a photoelectric conversion element.

The peripheral circuit region includes a vertical drive circuit 4, a column signal processing circuit 5, a horizontal drive circuit 6, an output circuit 7, and a control circuit 8.

The control circuit 8 receives an input clock and data giving a command of an operation mode and the like and outputs data of internal information and the like of the imaging element 1. Specifically, the control circuit 8 generates a clock signal or a control signal serving as a reference of operations of the vertical drive circuit 4, the column signal processing circuit 5, and the horizontal drive circuit 6, on the basis of a vertical synchronization signal, a horizontal synchronization signal, and a master clock. The control circuit 8 inputs these signals to the vertical drive circuit 4, the column signal processing circuit 5, and the horizontal drive circuit 6.

The vertical drive circuit 4 includes, for example, a shift register, selects a pixel drive wiring line, supplies a pulse for driving the pixel 2 to the selected pixel drive wiring line, and drives the pixel 2 on a row basis. Specifically, the vertical drive circuit 4 selectively scans the pixels 2 of the pixel array unit 3 sequentially in the vertical direction on a row basis, and supplies a pixel signal based on signal charges generated according to an amount of received light in the photoelectric conversion element of each pixel 2 to the column signal processing circuit 5 through the vertical signal line 9.

The column signal processing circuit 5 is disposed, for example, for each of columns of the pixels 2, and performs, for each of pixel columns, signal processing such as noise removal on signals output from the pixels 2 of one row. Specifically, the column signal processing circuit 5 performs signal processing such as correlated double sampling (CDS) for removing fixed pattern noise specific to the pixel 2, signal amplification, and analog/digital (A/D) conversion. A horizontal selection switch (not illustrated) is provided at an output stage of the column signal processing circuit 5 to be connected with a horizontal signal line 10.

The horizontal drive circuit 6 includes, for example, a shift register, sequentially selects the column signal processing circuits 5 by sequentially outputting horizontal scanning pulses, and causes each of the column signal processing circuits 5 to output a pixel signal to the horizontal signal line 10.

The output circuit 7 performs signal processing on signals sequentially supplied from each of the column signal processing circuits 5 through the horizontal signal line 10 and outputs processed signals. The output circuit 7 may perform only buffering, for example, or may perform black level adjustment, column variation correction, various types of digital signal processing, and the like.

An input/output terminal 12 is provided to externally exchange signals.

### Circuit Configuration of Pixel

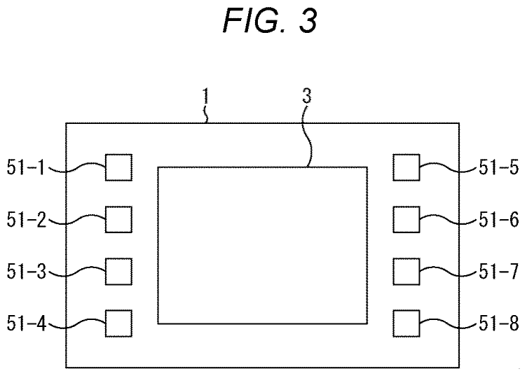

FIG. 3 is a diagram explaining a circuit configuration of the pixel 2. The figure illustrates an equivalent circuit of a pixel having a general four-transistor configuration. The pixel illustrated in the figure includes a photodiode 21 and four transistors (a transfer transistor 22, a reset transistor 24, an amplification transistor 25, and a selection transistor 26).

The photodiode 21 generates a current corresponding to an amount of received light by photoelectric conversion. The anode of the photodiode 21 is connected to the ground, and the cathode thereof is connected to the drain of the transfer transistor 22. Various control signals are input to the pixel 2 from a reset signal generation circuit and various drivers of the vertical drive circuit 4.

A signal line for transmitting a transfer gate signal is connected to the gate of the transfer transistor 22. The source of the transfer transistor 22 is connected to a connection point between the source of the reset transistor 24 and the gate of the amplification transistor 25. The connection point forms a floating diffusion 23 that is a capacitance for accumulating signal charges.

The transfer transistor 22 is turned on when a transfer signal is input to the gate through the signal line, and transfers signal charges (here, photoelectrons) accumulated by photoelectric conversion by the photodiode 21 to the floating diffusion 23.

A signal line for transmitting a reset signal is connected to the gate of the reset transistor 24, and a constant voltage source VDD is connected to the drain. The reset transistor 24 is turned on when the reset signal is input to the gate through the signal line, and resets the floating diffusion 23 to a voltage of the constant voltage source VDD. On the other hand, in a case where the reset signal is not input to the gate through the signal line, the reset transistor 24 is turned off, and a predetermined potential barrier is formed between the floating diffusion 23 and the constant voltage source VDD.

The amplification transistor 25 constitutes a source follower having the gate connected to the floating diffusion 23, the drain connected to the constant voltage source VDD, and the source connected to the drain of the selection transistor 26.

The selection transistor 26 has the gate connected to a signal line of a selection signal and the source connected to the vertical signal line 9. The selection transistor 26 is turned on when a control signal (address signal or select signal) is input to the gate through the signal line, and is turned off in a case where the control signal is not input to the gate through the signal line.

When the selection transistor 26 is turned on, the amplification transistor 25 amplifies the voltage of the floating diffusion 23 and outputs the amplified voltage to the vertical signal line 9. The voltage output from each pixel through the vertical signal line 9 is input to the column signal processing circuit 5.

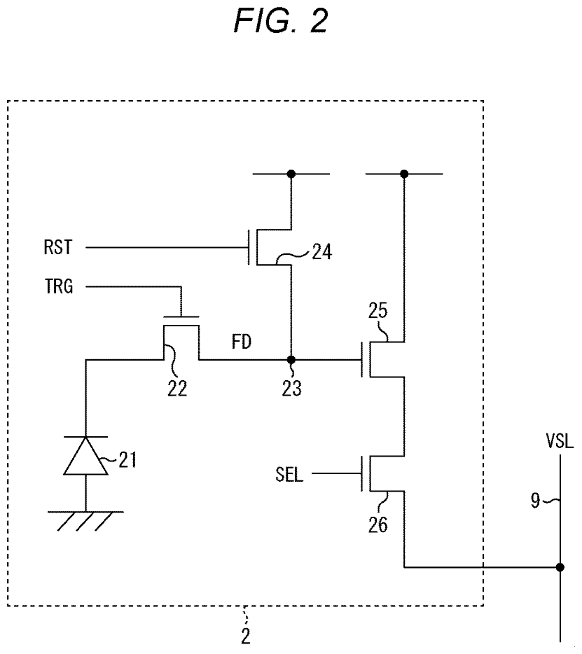

Note that, as the circuit configuration of the pixel, it is possible to adopt not only the configuration illustrated in FIG. 2 but also various known configurations such as a three-transistor configuration and another four-transistor configuration. For example, another four-transistor configuration includes a configuration in which the selection transistor 26 is disposed between the amplification transistor 25 and the constant voltage source VDD.

### Planar Configuration Example of Pixel

FIG. 3 is a diagram illustrating a planar configuration example of the imaging element 1. FIG. 3 illustrates a planar configuration example when viewed from a light incident surface side of the imaging element 1. The pixel array unit 3 is provided in a central region of the pixel 2. Pads 51-1 to 51-8 are provided in an outer peripheral region of the pixel array unit 3.

The pads 51-1 to 51-4 are provided on the left side in the figure of the pixel array unit 3, and the pads 51-5 to 51-8 are provided on the right side in the figure. In the following description, in a case where it is not necessary to individually distinguish the pads 51-1 to 51-8 from each other, they will be simply described as pads 51. Similar description will be made for other portions.

The pad 51 is a portion onto which an inspection needle is dropped, for example, when the imaging element 1 is inspected at the time of manufacturing. Here, the description will be continued on the assumption that the pad is the portion onto which the inspection needle is dropped, but for example, the pad may be used as a terminal to be connected to an external circuit or may be used for other purposes.

### cross-sectional Configuration Example of Pixel

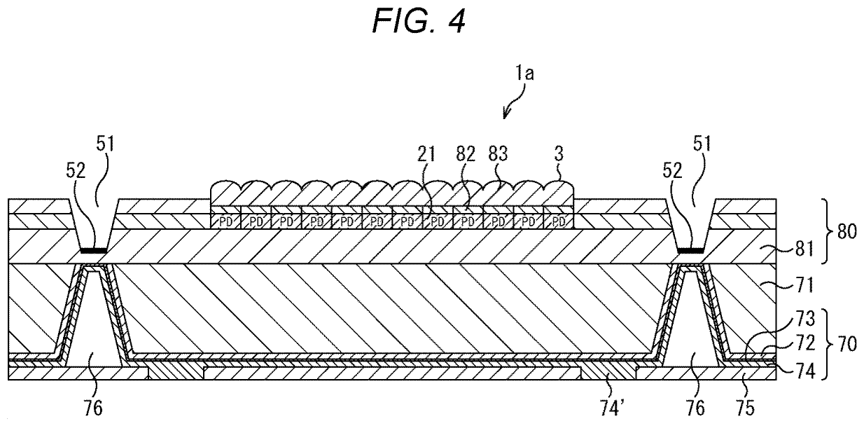

FIG. 4 is a diagram illustrating a cross-sectional configuration example of an imaging element 1a according to a first embodiment. The imaging element 1a receives and photoelectrically converts light incident from a subject, and outputs an electric signal corresponding to an amount of light.

The imaging element 1a can be a wafer-level chip size package (WLCSP) formed by a method of forming terminals, wiring, and the like before cutting a wafer (silicon wafer) and then dicing the wafer.

In the imaging element 1a, one or a plurality of layers is formed on each of the front surface side (a surface side on an opposite side from a light incident surface, lower side in the figure) and the back surface side (a light incident surface side, upper side in the figure) of a semiconductor substrate 80. These layers are formed by, for example, a coating method such as a chemical vapor deposition method, a physical vapor deposition method, or a spin coating method, a lithography technique, bonding of a support substrate, a peripheral circuit substrate manufactured separately, or the like. A color filter 82 and an on-chip lens 83 are stacked on the back surface side that is a light receiving surface of the semiconductor substrate 80.

The pad 51 is opened in the semiconductor substrate 80. The pad 51 is formed to a depth substantially penetrating the semiconductor substrate 80, and an electrode 52 is formed at the bottom thereof. The electrode 52 is formed in an exposed state. As described above, the pad 51 is the portion onto which the needle is dropped at the time of inspection, in other words, to be connected to an inspection device, and the needle at the time of inspection is connected to the electrode 52.

A wiring layer 81 is stacked on the front surface side of the semiconductor substrate 80. A rewiring layer 70 is provided on the front side of a support substrate 71 that is further on the front side of the wiring layer 81. Note that another layer may be stacked and interposed between the layers stacked on the surfaces of the semiconductor substrate 80. As the semiconductor substrate 80, for example, a semiconductor substrate is used such as a silicon wafer.

The type of the imaging element 1a is not particularly limited, and may be a front-illuminated type or a back-illuminated type. The imaging element 1a may be any of a complementary metal oxide semiconductor (CMOS) system, a charge coupled device (CCD) system, or another system. In the case of a front-illuminated type imaging element, the wiring layer 81 is formed between the semiconductor substrate 80 and the color filter 82. Note that, in the following description, a back-illuminated type CMOS image sensor will be described as an example of the imaging element 1a of the WLCSP.

In the semiconductor substrate 80, a plurality of the photodiodes 21 as photoelectric conversion elements is arranged in parallel in a region corresponding to the pixel array unit 3. Although not illustrated, pixel transistors (transfer transistor, reset transistor, amplification transistor, selection transistor) are also provided inside the semiconductor substrate 80 along the front surface of the pixel array unit 3. The pixel transistors are basically provided in each pixel. However, in the case of an FD sharing system in which a floating diffusion (FD) is shared by a plurality of pixels, the transfer transistor is provided for each pixel, but the other pixel transistors are provided for each of FDs.

The semiconductor substrate 80 is connected to a peripheral circuit via pixel drive lines and vertical signal lines constituting the wiring layer 81 stacked on the front surface of the semiconductor substrate 80. The peripheral circuit includes some or all of the vertical drive circuit 4, the column signal processing circuit 5, the horizontal drive circuit 6, the control circuit 8, and the like. The peripheral circuit is formed in a peripheral circuit region or a peripheral circuit substrate provided outside the pixel array unit 3.

A plurality of the color filters 82 is stacked on the back surface of the semiconductor substrate 80 so as to correspond to respective positions of the photodiodes 21. On the color filters 82, a plurality of the on-chip lenses 83 is stacked in correspondence with respective positions of the color filters 82. The on-chip lenses 83 are formed using an inorganic film having a high refractive index, for example, a SiN film (silicon nitride film), a SiON film (silicon nitride oxide film), a Sio film (silicon oxide film), or the like, and can be formed by an etch-back method. These films have a refractive index of about 1.4 to 2.0.

As described above, the wiring layer 81 is stacked on the front surface of the semiconductor substrate 80. In a case where the peripheral circuit substrate is separately manufactured and three-dimensionally stacked and integrated with the image sensor, the peripheral circuit substrate is bonded to the front side of the wiring layer 81. The support substrate 71 such as bulk silicon is bonded to a further front side of the wiring layer 81 or the front side of the peripheral circuit substrate.

In the imaging element 1a, a through electrode (for example, through silicon via (TSV)) 76 is formed penetrating the support substrate 71 from the front surface (side surface not facing the semiconductor substrate 80) toward the back surface. The through electrode 76 is provided to penetrate the support substrate 71.

The rewiring layer 70 is stacked on the front surface of the support substrate 71. The rewiring layer 70 includes a rewiring line 74 as a metal wiring line formed on the front surface side of the support substrate 71, solder resist 75 covering the rewiring line 74, and a land 74′ serving as a connection terminal of the imaging element 1a. In the example illustrated in FIG. 4, a barrier metal 73 is further formed on the upper side in the figure of the rewiring line 74, and an insulating film 72 is further formed on the upper side in the figure of the barrier metal 73.

The insulating film 72 includes, for example, silicon oxide (SiO). The barrier metal 73 includes for example, Ti (titanium). The rewiring line 74 includes, for example, copper (Cu). The insulating film 72, the barrier metal 73, and the rewiring line 74 are also formed on the side wall and the bottom (in the figure, the pad 51 side) in the through electrode 76. The rewiring line 74 electrically connects a wiring line in the imaging element 1a and the land 74′ provided on the front surface of the support substrate 71 to each other.

The land 74′ is formed at a position corresponding to a connection terminal of a substrate to be a mounting destination of the imaging element 1a, and the connection terminal of the substrate is connected to a wiring line connected to the through electrode 76 via the rewiring line 74 by being connected to the land 74′. The through electrode 76 and the rewiring line 74 are covered with and insulated from the solder resist 75 except for the land 74′. Note that, in the present embodiment, a land grid array (LGA) structure has been described as an example, but a solder ball may be formed on the land 74′ to form a ball grid array (BGA) structure. Furthermore, a structure may be formed in which a metal post is erected on the land 74′.

By adopting the rewiring layer 70 via the through electrode 76, it is not necessary to route a metal wiring line (wire) so as to wrap around a side surface of the imaging element 1a, and there are advantages such as reduction in a mounting area of a module, reduction in the number of components, and improvement in efficiency of a manufacturing process. Furthermore, since it is not necessary to route the metal wiring line, a wiring length is shortened, so that electrical characteristics are improved, and fine and free design is possible. As a result, it is possible to improve signal transmission quality, and improve quality (for example, image quality in image processing) of various types of signal processing in the subsequent stage using an output signal of the module.

The imaging element 1a illustrated in FIG. 4 can have a configuration in which a glass substrate is not stacked on the light incident surface side (side on which the on-chip lens 83 is formed) of the imaging element 1a. By adopting a structure in which the glass substrate is not stacked, it is possible to further reduce the height of (thin) the imaging element 1a.

The pad 51 and the through electrode 76 of the imaging element 1 illustrated in FIG. 4 each are formed in a tapered shape. In the example illustrated in FIG. 4, the opening is formed to be wide and the bottom is formed to be narrow. Note that, here, a portion having a wider opening on the taper is defined as the opening, and a portion having a narrower opening is defined as the bottom.

The pad 51 is formed such that the opening on the upper side in the figure is wide, and the bottom side on which the electrode 52 is provided is narrow. The through electrode 76 is formed such that the opening on the side where the solder resist 75 is formed is wide, and the opening on the bottom side where the pad 51 side is formed is narrow.

A shape of each of the pad 51 and the through electrode 76 in a cross-sectional view may be a tapered shape (trapezoidal shape) or a shape other than the tapered shape, for example, a rectangular shape.

The electrode 52 provided at the bottom of the pad 51 is provided in a state of being exposed. The through electrode 76 has a structure including a space. A space between the bottom and the opening (solder resist 75) of the through electrode 76 is a cavity. According to the configuration in which the cavity is provided, an amount of material to be used can be reduced by an amount by which the cavity's portion is not filled with the material.

The pad 51 and the through electrode 76 are disposed on a straight line in the longitudinal direction (vertical direction in the figure) in the cross-sectional structure illustrated in FIG. 4. In a cross-sectional view, the central axis of the pad 51 and the central axis of the through electrode 76 are located on a substantially straight line (including a case where a slight deviation occurs). Although not illustrated, the pad 51 and the through electrode 76 are formed in a state where there is an overlapping region in plan view.

Since the electrode 52 is exposed, for example, it is possible to drop the inspection needle on the electrode 52 at the time of inspection at the time of manufacturing to connect to the inspection device, and perform inspection of the imaging element 1a.

### Configuration Example of Imaging Element According to Second Embodiment

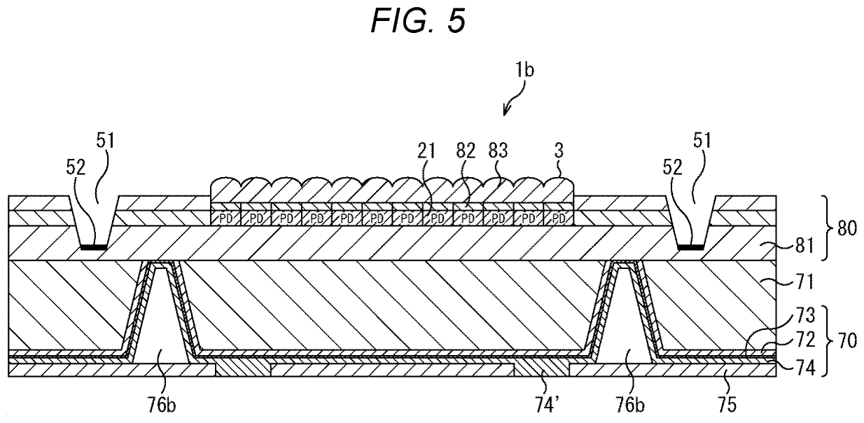

FIG. 5 is a diagram illustrating a cross-sectional configuration example of an imaging element 1b according to a second embodiment. In the imaging element 1b (FIG. 5) according to the second embodiment and the imaging element 1a (FIG. 4) according to the first embodiment, the same portions are denoted by the same reference numerals, and the description thereof is appropriately omitted.

Comparing the imaging element 1b illustrated in FIG. 5 with the imaging element 1a illustrated in FIG. 4, the imaging element 1b is different from the imaging element 1a in that a position where a through electrode 76b is formed is formed inside, and the other points are similar.

The imaging element 1b illustrated in FIG. 5 has a structure in which the pad 51 and the through electrode 76b are formed at positions shifted from each other since the through electrode 76b is moved inward. For example, in a positional relationship between the pad 51 and the through electrode 76b on the left side in FIG. 5, the through electrode 76b is formed at a position closer to the center side of the imaging element 1b than the pad 51. Similarly, in a positional relationship between the pad 51 and the through electrode 76b on the right side in FIG. 5, the through electrode 76b is formed at a position closer to the center side of the imaging element 1b than the pad 51.

FIG. 4 is referred to again. In the imaging element 1a illustrated in FIG. 4, the pad 51 and the through electrode 76a (in order to distinguish from the through electrode 76b, the through electrode 76 is described as the through electrode 76a) are disposed on a straight line in the longitudinal direction (vertical direction in the figure). On the other hand, in the imaging element 1b illustrated in FIG. 5, the pad 51 and the through electrode 76b are not disposed on a straight line in the longitudinal direction (vertical direction in the figure), and are formed such that the center line of the pad 51 and the center line of the through electrode 76b are at positions shifted from each other.

In the imaging element 1a illustrated in FIG. 4, since the pad 51 and the through electrode 76a are formed on a straight line, a distance between the bottom of the pad 51 and the bottom of the through electrode 76a is short. That is, a thickness of the substrate between the pad 51 and the through electrode 76a is thin. At the time of inspection, the inspection needle is dropped on the electrode 52 of the pad 51, in other words, the needle is dropped on a thin portion of the substrate, and thus, there is a possibility that a crack or the like occurs in the thin portion. In a case where there is such a possibility, it is necessary to perform inspection by another method, for example, an inspection method such as taking out the imaging element 1a singulated from the wafer and connecting the inspection needle to the land 74′ for inspection, and there is a possibility that time and effort required for the inspection increase.

In the imaging element 1b illustrated in FIG. 5, since the pad 51 and the through electrode 76b are not formed on a straight line, the through electrode 76b is not located on the lower side of the bottom (electrode 52) of the pad 51, and there is no cavity region. Thus, the strength of the portion of the pad 51 is maintained, and even if the inspection needle is dropped on the electrode 52 of the pad 51 at the time of inspection, it is possible to prevent the portion from being damaged. Thus, at the time of inspection, the imaging element 1b can be inspected in a wafer state, and the time and effort required for the inspection can be reduced.

In the structure of the imaging element 1b, since the electrode 52 is exposed, for example, it is possible to drop the inspection needle on the electrode 52 at the time of inspection at the time of manufacturing to connect to the inspection device, and perform inspection of the imaging element 1b.

Furthermore, the strength of a region where the electrode 52 is provided can be a strength that can sufficiently withstand the force applied when the needle is dropped at the time of inspection, and it is possible to prevent a crack or the like from occurring in the electrode 52 and a film between the wiring layers below the electrode 52. Conductivity of the pad 51 and stable connection resistance can be obtained.

Also in the structure of the imaging element 1b illustrated in FIG. 5, since the imaging element 1b has a configuration equivalent to that of the imaging element 1a (FIG. 4), for example, no glass substrate is disposed and the land 74′ is formed, the imaging element 1b can be thinned (downsized).

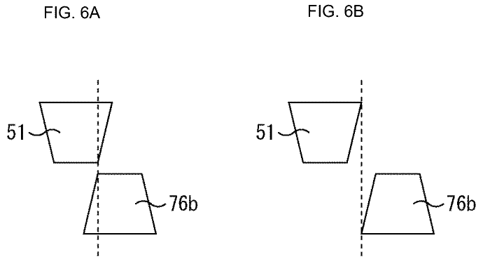

A shift between the pad 51 and the through electrode 76b will be described with reference to FIG. 6. An example illustrated in A of FIG. 6 illustrates a state where the pad 51 and the through electrode 76b are at positions shifted from each other but partially overlap each other. When there is such an overlap, there is a possibility that the substrate is thin at a portion where there is the overlap and weak in terms of strength, and thus, the pad 51 and the through electrode 76b are formed at positions where there is no such overlap.

That is, as illustrated in B of FIG. 6, the pad 51 and the through electrode 76b are formed at positions shifted from each other and in a state where there is no overlapping portion. In a case where each of the pad 51 and the through electrode 76b are formed in a tapered shape, the pad 51 and the through electrode 76b are formed at positions where the end of the opening of the pad 51 and the end of the opening of the through electrode 76b do not overlap each other. By forming the pad 51 and the through electrode 76b in a state where there is no overlap in this manner, it is possible to have a configuration in which there is no portion that is weak in terms of strength.

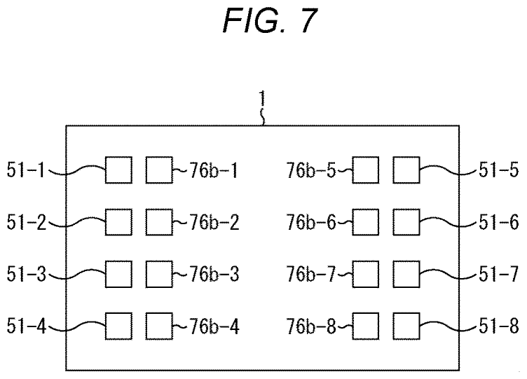

As described above, in a case where there is no overlapping portion between the pad 51 and the through electrode 76b, a planar configuration example is as illustrated in FIG. 7. Referring to FIG. 7, in a case where the imaging element 1b is viewed from the pad 51 side, (a cavity portion of) the through electrode 76b is formed on the left side or the right side of the pad 51, and the pad 51 and the through electrode 76b are formed such that there is no overlapping region in plan view.

As described above, in plan view, the pad 51 and the through electrode 76b are disposed at positions shifted from each other, and are formed at positions where there is no overlapping portion.

### Regarding Manufacturing of Imaging Element

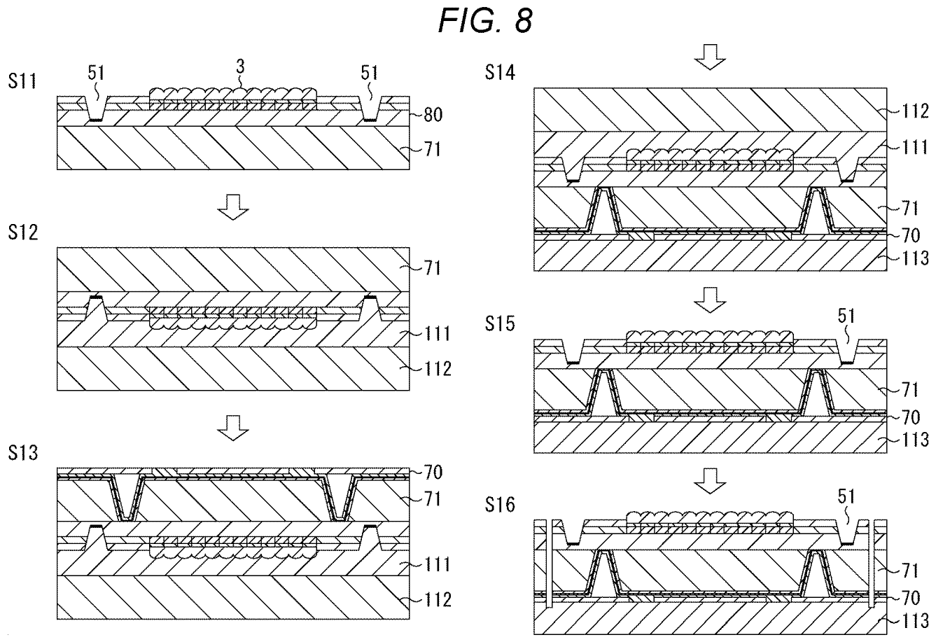

Manufacturing of the imaging element 1b having the cross-sectional configuration illustrated in FIG. 6 will be described with reference to FIG. 8.

In a process S11, in the pixel array unit 3 of the semiconductor substrate 80, constituent elements (element isolation, photodiode 21, source region/drain region of pixel transistor, and the like) of the plurality of unit pixels 2 are formed in a two-dimensional arrangement in a two-dimensional matrix form by, for example, ion implantation from the front surface side of the semiconductor substrate 80.

On the front surface of the semiconductor substrate 80, the wiring layer 81 is stacked in which a plurality of layers of wiring lines is disposed with an interlayer insulating film interposed therebetween. In the wiring layer 81, the pad 51 for outputting a signal to the outside of the chip is opened, and the electrode 52 is formed at the bottom of the pad 51. An interlayer insulating film such as a SiO₂ film is stacked on the wiring layer 81, and the interlayer insulating film is planarized by chemical mechanical polishing (CMP), so that the front surface of the wiring layer 81 is formed in a substantially flat surface.

The support substrate 71 is bonded to the substantially flat surface of the wiring layer 81 for reinforcement. As the support substrate 71, for example, a semiconductor substrate is used such as bulk silicon.

A transparent planarization film (not illustrated) and the color filter 82 are formed on the back surface of the semiconductor substrate 80. The planarization film is formed such that, for example, a thermoplastic resin is deposited by a spin coating method and then a thermal curing treatment is performed. For example, the color filter 82 with Bayer array is formed on the planarization film as a primary color filter including green, red, and blue. The color filter 82 is formed corresponding to each unit pixel 2, and includes, for example, three color filters of a red color filter, a green color filter, and a blue color filter. The color filter 82 is not limited to the three primary colors of light, and a complementary color filters can be used, or a white color filter can be used in combination. A planarization film may be further provided on the upper surface of the color filter 82, as necessary.

The on-chip lens 83 is formed on the color filter 82. The on-chip lens 83 is formed, for example, by a method in which a thermosetting transparent resin material such as an acrylic resin material, a styrene resin material, or an epoxy resin material is spin-coated and thermally cured, an inorganic material of SiO, SiN, or SiON is deposited by a plasma CVD method, and then resist shaped like a lens is patterned and etched back.

In the peripheral circuit region on the outer periphery of the pixel array unit 3, a through hole penetrating the semiconductor substrate 80 and penetrating to the wiring layer 81 or the electrode 52 formed on the peripheral circuit substrate is formed by dry etching or the like, so that a portion to be the pad 51 is opened. By inserting the inspection needle (probe) into the pad 51 and bringing it into contact with the electrode 52, it is possible to perform inspection such as operation confirmation of the peripheral circuit. As will be described later, the inspection can be performed in a state where the chip (imaging element 1b) is on a dicing ring after dicing, in other words, in a state where the wafer state is maintained.

In a process S12, the semiconductor substrate 80 to which the support substrate 71 is bonded is reversed, and the back surface of the semiconductor substrate 80 is the upper surface. An adhesive layer 111 is formed on the back surface of the semiconductor substrate 80 that is the upper surface. For example, an adhesive material is applied with use of a spin coating method and a film is formed, whereby the adhesive layer 111 is formed. The adhesive material enters and fills the inside of the above-described through hole (pad 51) to be solidified. That is, the adhesive material that adheres to a temporary substrate 112 and solidifies has a protrusion shape in which a part thereof protrudes toward the inside of the pad 51.

The temporary substrate 112 is bonded to the semiconductor substrate 80 with the adhesive layer 111 interposed therebetween. The temporary substrate 112 is bonded to the semiconductor substrate 80, so that the imaging element 1 being manufactured is reinforced, rigidity is improved as a whole, and resistance to warpage and deflection is improved. The semiconductor substrate 80 and the support substrate 71 reinforced by the temporary substrate 112 are entirely reversed, and are made to be in a state where the front surface of the support substrate 71 is oriented upward. As a result, it is possible to perform processing of forming the rewiring layer 70 on the front surface side of the support substrate 71.

In a process S13, the support substrate 71 is polished and ground from the front surface side by back grinding, CMP, or the like to be thinned. As a result, processing for forming the through electrode 76 is facilitated, and the overall height of the imaging element 1 can be reduced. The rewiring layer 70 is formed on the front surface of the thinned support substrate 71.

Formation of the rewiring layer 70 is performed by forming a through hole penetrating the support substrate 71 and forming a film of a metal such as Cu plating inside the through hole. In a case where the through hole to be the through electrode 76 is formed so as to be in line with the pad 51 as in the imaging element 1a illustrated in FIG. 4, the through hole is formed at a position in line with the pad 51. Furthermore, in a case where the through hole to be the through electrode 76 is formed to be at a position shifted from the pad 51 as in the imaging element 1b illustrated in FIG. 5, the through hole is formed at a position shifted from the pad 51.

Since the insulating film 72, the barrier metal 73, and the rewiring line 74 are formed inside the through electrode 76 and on the bottom surface of the support substrate 71 as described with reference to FIG. 4, layers thereof are formed in this order.

The land 74′ is formed on the front surface of the support substrate 71 by photolithography. Thereafter, a portion other than the land 74′ is covered with the solder resist 75. A solder ball (not illustrated) may be formed on the land 74′ to form a BGA structure. A connection destination of the through electrode 76 can be used as a terminal for inputting and outputting a signal to and from the outside in the peripheral circuit of the imaging element 1.

In a process S14, a dicing ring 113 is pasted to the front surface side of the rewiring layer 70, and the whole is reversed. As a result, a state is obtained where the temporary substrate 112 is again oriented upward.

In a process S15, debonding of peeling the temporary substrate 112 from the imaging element 1 is performed, and the adhesive layer 111 that remains adhering to the surfaces of the on-chip lens 83 and the like and the inside of the pad 51 is chemically removed by dissolution with an organic solvent or a chemical etching method. Examples of the debonding include mechanical debonding, debonding by laser irradiation, and debonding by heat blow. As a result, the on-chip lens 83 and the pad 51 (electrode 52) are exposed.

In a process S16, the imaging element 1 is diced along a scribe line and singulated, whereby the above-described imaging element 1 is obtained.

The state of the process S16 is a state where the singulated imaging element 1 (chip) is on the dicing ring 113. In other words, it is a state where the wafer state is maintained. In such a wafer state, imaging characteristics of the imaging element 1 can be electrically measured.

In the imaging element 1b illustrated in FIG. 5, since the pad 51 and the through electrode 76b are disposed at positions shifted from each other, the portion of the pad 51 is not weakened in terms of strength, and there is a low possibility that the imaging element 1b is damaged even if the inspection needle is dropped on the electrode 52.

Thus, the imaging characteristics of the imaging element 1b can be measured in a state where the singulated imaging element 1b is pasted on the dicing ring 113. Since the individual imaging element 1 can be inspected in the wafer state, it is possible to reduce the time and effort required for the inspection.

Since the imaging element 1 described later has a structure in which the strength is not weakened even if the pad 51 and the through electrode 76 are formed on a straight line, the imaging characteristics can be measured in the process S16.

### Configuration Example of Imaging Element According to Third Embodiment

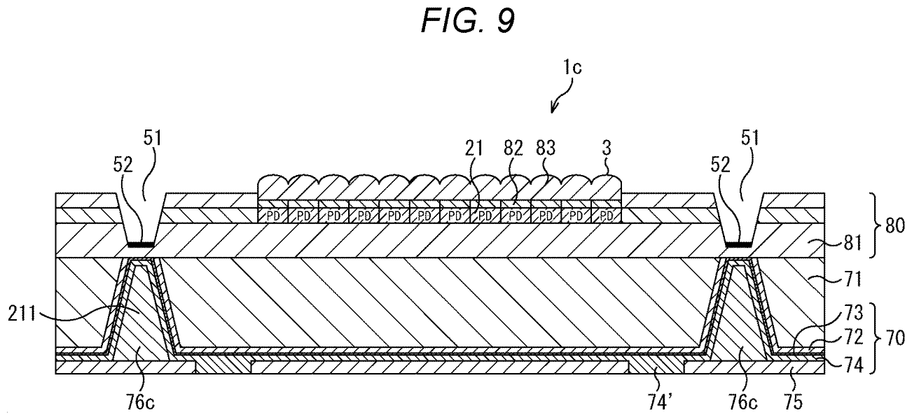

FIG. 9 is a diagram illustrating a cross-sectional configuration example of an imaging element 1c according to a third embodiment. In the imaging element 1c (FIG. 9) according to the third embodiment and the imaging element 1a (FIG. 4) according to the first embodiment, the same portions are denoted by the same reference numerals, and the description thereof is appropriately omitted.

Comparing the imaging element 1c illustrated in FIG. 9 with the imaging element 1a illustrated in FIG. 4, the imaging element 1c is different from the imaging element 1a in that a through electrode 76c is filled with a predetermined material and a reinforcing film 211 is provided, and the other points are similar.

The through electrode 76a (FIG. 4) of the imaging element la has a configuration including a cavity, but a portion corresponding to the cavity of the through electrode 76c (FIG. 9) of the imaging element 1c is filled with the predetermined material, and the reinforcing film 211 is formed so that there is no cavity.

The inside of the through electrode 76c of the imaging element 1c is filled with an inorganic material, for example, silicon oxide (SiO) or the like, and the reinforcing film 211 is formed. The imaging element 1c illustrated in FIG. 9 has a configuration in which the reinforcing film 211 is formed with respect to the imaging element 1a according to the first embodiment.

In the imaging element 1c, the pad 51 and the through electrode 76c are disposed on a straight line, but since the reinforcing film 211 is formed in the through electrode 76c, the strength of a portion between the pad 51 and the through electrode 76c can be compensated. That is, in the imaging element 1c, the portion between the pad 51 and the through electrode 76c is not weakened in terms of strength, and the imaging element 1c can be obtained in which the strength is maintained.

As described above, silicon oxide can be used as the material of the reinforcing film 211. Furthermore, it is also possible to use a material having hardness similar to that of silicon oxide. Furthermore, an organic material may be used.

In a case where the reinforcing film 211 includes an organic material, it is also possible to form the reinforcing film 211 in the through electrode 76 (in the through hole) at the time of forming the solder resist 75, by using the same material as the solder resist 75.

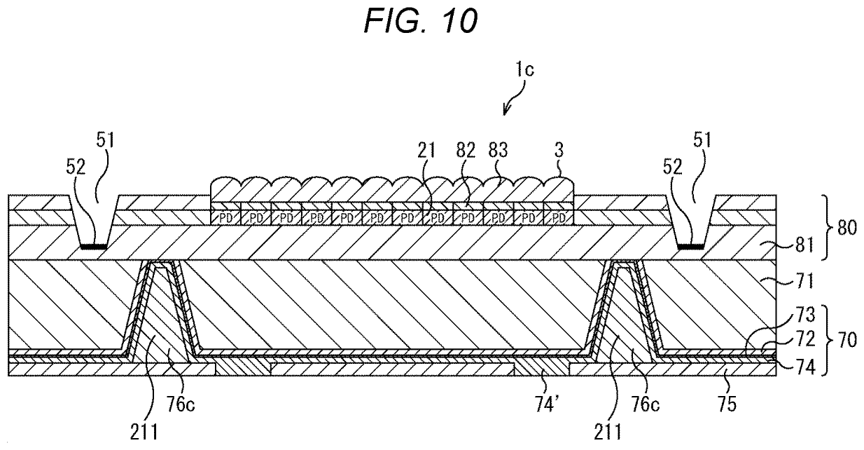

The imaging element 1c illustrated in FIG. 9 illustrates a configuration in a case where the third embodiment is applied to the imaging element 1a according to first embodiment illustrated in FIG. 4. As illustrated in FIG. 10, the third embodiment can also be applied to the imaging element 1b according to the second embodiment illustrated in FIG. 5.

The imaging element 1c illustrated in FIG. 10 has a configuration in which the pad 51 and the through electrode 76c are disposed at positions shifted from each other, and the reinforcing film 211 is formed in the through electrode 76c. In this case, it is possible to further reduce a possibility that the strength decreases in a region of the through electrode 76c, and to improve the strength as the imaging element 1c.

### Configuration Example of Imaging Element According to Fourth Embodiment

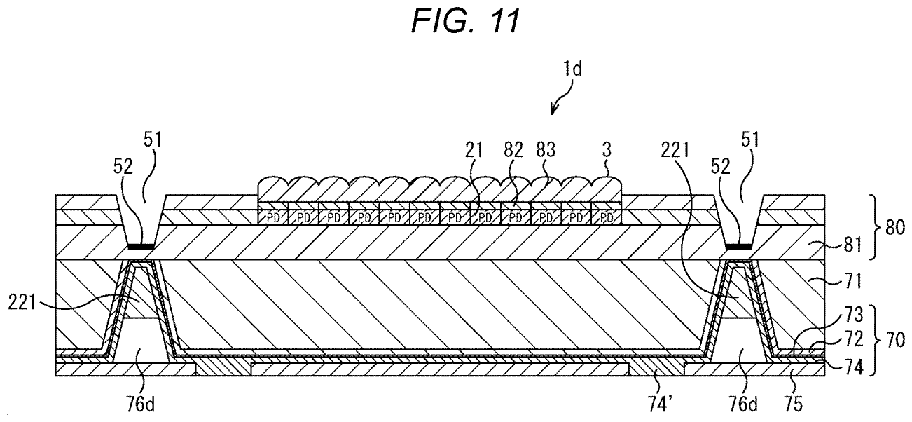

FIG. 11 is a diagram illustrating a cross-sectional configuration example of an imaging element 1d according to a fourth embodiment. In the imaging element 1d (FIG. 11) according to the fourth embodiment and the imaging element 1a (FIG. 4) according to the first embodiment, the same portions are denoted by the same reference numerals, and the description thereof is appropriately omitted.

Comparing the imaging element 1d illustrated in FIG. 11 with the imaging element 1a illustrated in FIG. 4, the imaging element 1d is different from the imaging element 1a in that a reinforcing film 221 is provided on the pad 51 side in the through electrode 76c, and the other points are similar. In a case where the imaging element 1d is compared with the imaging element 1c illustrated in FIG. 9, the imaging element 1c illustrated in FIG. 9 has a configuration in which the reinforcing film 211 is formed in a state where there is no cavity in the through electrode 76c, whereas the imaging element 1d illustrated in FIG. 11 has a configuration in which the reinforcing film 221 is formed in a state where there is no cavity on the pad 51 side in a through electrode 76d, and there is a cavity on the side away from the pad 51 (solder resist 75 side).

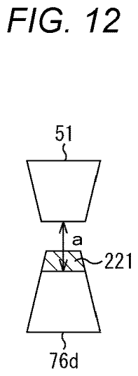

As described above, by forming the reinforcing film 221 at a predetermined depth (thickness) on the bottom side of the through electrode 76d, it is possible to secure the strength of the portion of the pad 51. In order to ensure the strength of the portion of the pad 51, as illustrated in FIG. 12, the reinforcing film 221 is formed so that the bottom (electrode 52) of the pad 51 and the bottom of the cavity of the through electrode 76d are separated from each other by a distance a or more.

By forming the reinforcing film 221, it is possible to separate the bottom (electrode 52) of the pad 51 and the bottom of the cavity of the through electrode 76d from each other by the distance a or more, so that it is possible to have a structure that prevents the strength of the portion of the pad 51 from deteriorating.

Silicon oxide can be used as the material of the reinforcing film 221. Furthermore, it is also possible to use an inorganic material having hardness similar to that of silicon oxide. Furthermore, an organic material may be used.

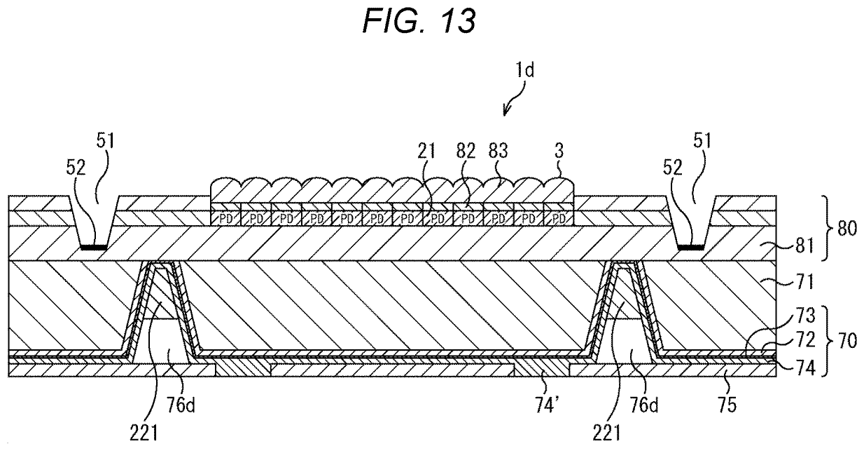

The imaging element 1d illustrated in FIG. 11 illustrates a configuration in a case where the fourth embodiment is applied to the imaging element 1a according to the first embodiment illustrated in FIG. 4. As illustrated in FIG. 13, the fourth embodiment can also be applied to the imaging element 1b according to the second embodiment illustrated in FIG. 5.

The imaging element 1d illustrated in FIG. 13 has a configuration in which the pad 51 and the through electrode 76c are disposed at positions shifted from each other, and the reinforcing film 221 is formed with a predetermined thickness (depth) on the pad 51 side in the through electrode 76d. In this case, it is possible to further reduce a possibility that the strength decreases due to the through electrode 76d, and to improve the strength as the imaging element 1d.

### Configuration Example of Imaging Element According to Fifth Embodiment

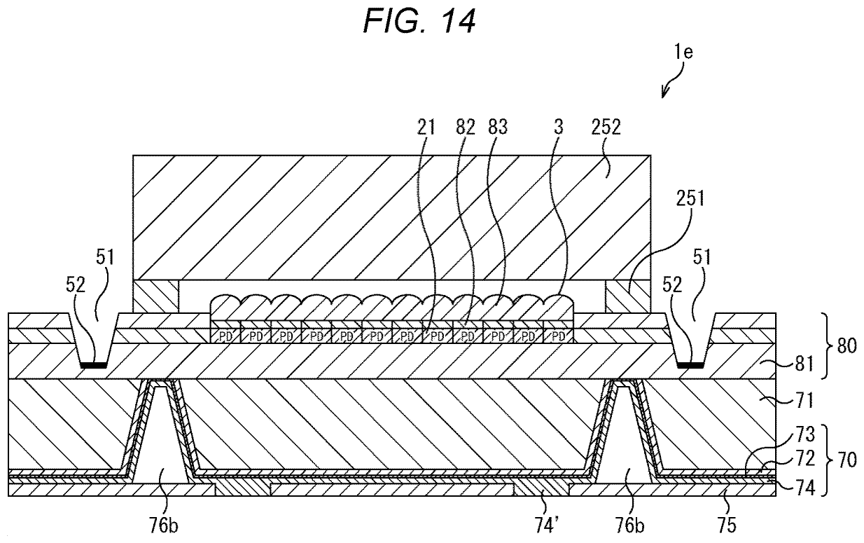

FIG. 14 is a diagram illustrating a cross-sectional configuration example of an imaging element le according to a fifth embodiment. In the first to fourth embodiments, a case has been described of a glassless structure in which the glass substrate is not disposed on the imaging element 1, but a configuration may be adopted in which the glass substrate is disposed.

In the imaging element le illustrated in FIG. 14, a glass substrate 252 is disposed on the imaging element 1b (FIG. 5) according to the second embodiment with a base 251 interposed therebetween. The base 251 is disposed at a position where there is no portion overlapping with the opening of the pad 51. The glass substrate 252 is also disposed so as not to have a portion overlapping with the pad 51 and is disposed so as to be located on the pixel array unit 3 (on an effective pixel region).

By disposing the base 251 at a position at which the base 251 does not overlap with the pad 51, it is possible to prevent a weight of the glass substrate 252 from being applied to the pad 51. Furthermore, since it is not a structure that prevents the opening of the pad 51, the pad 51 can be used even after the glass substrate 252 is disposed.

The imaging element le illustrated in FIG. 14 illustrates an example in which the glass substrate 252 is disposed on the imaging element 1b (FIG. 5) according to the second embodiment with the base 251 interposed therebetween. However, it is also possible to have a configuration in which the glass substrate 252 is disposed on the imaging element 1a (FIG. 4) according to the first embodiment, on the imaging element 1c (FIG. 9, FIG. 10) according to the third embodiment, or on the imaging element 1d (FIG. 11, FIG. 13) according to the fourth embodiment with the base 251 interposed therebetween.

### Configuration Example of Imaging Element According to Sixth Embodiment

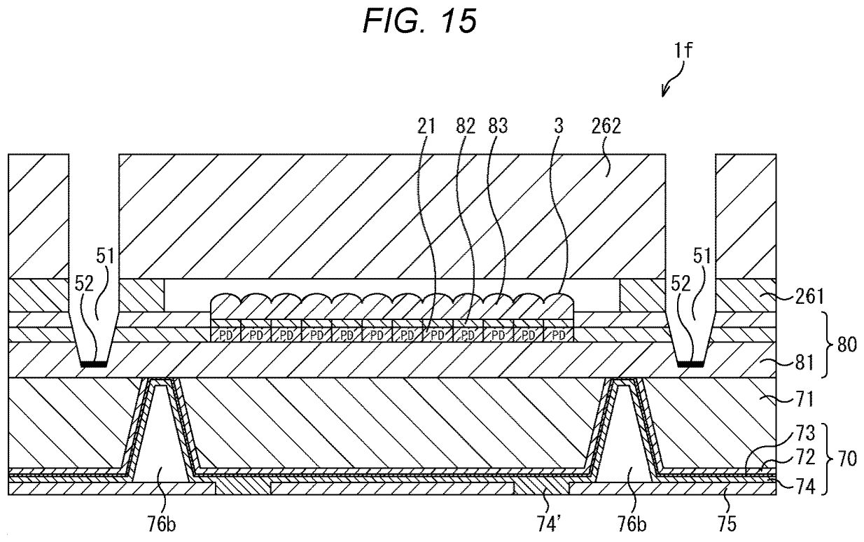

FIG. 15 is a diagram illustrating a cross-sectional configuration example of an imaging element 1f according to a sixth embodiment. Similarly to the imaging element le according to the fifth embodiment, the imaging element 1f illustrated in FIG. 15 also has a configuration in which a glass substrate is disposed.

In the imaging element 1f illustrated in FIG. 15, a glass substrate 262 is disposed on the imaging element 1b (FIG. 5) according to the second embodiment with a base 261 interposed therebetween. An opening having about the same size as the opening of the pad 51 is formed in the base 261 and the glass substrate 262. The base 261 and the glass substrate 262 are disposed so that there is no portion overlapping with the pad 51, and present on the pixel array unit 3 (on the effective pixel region) and on the peripheral circuit region. In other words, the glass substrate 262 is disposed at a position, with a size that covers the light incident surface side of the imaging element 1f.

By providing the base 261 and the glass substrate 262 with an opening (through hole) that is about the same as the opening of the pad 51 or larger than the opening of the pad 51 so that there is no region overlapping with the pad 51, it is possible to prevent the weight of the base 261 and the glass substrate 262 from being applied to the pad 51. Furthermore, since it is not a structure that prevents the opening of the pad 51, the pad 51 can be used even after the glass substrate 262 is disposed.

The imaging element 1f illustrated in FIG. 15 illustrates an example in which the glass substrate 262 is disposed on the imaging element 1b (FIG. 5) according to the second embodiment with the base 261 interposed therebetween. However, it is also possible to have a configuration in which the glass substrate 262 is disposed on the imaging element 1a (FIG. 4) according to the first embodiment, on the imaging element 1c (FIG. 9, FIG. 10) according to the third embodiment, or on the imaging element 1d (FIG. 11, FIG. 13) according to the fourth embodiment with the base 261 interposed therebetween.

### Configuration Example of Imaging Element According to Seventh Embodiment

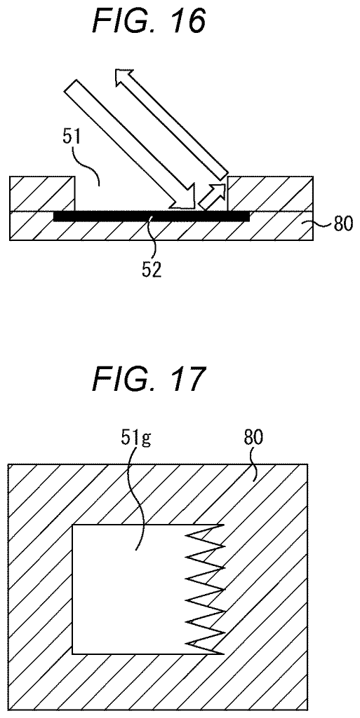

The imaging element 1 according to the first to sixth embodiments is in a state where the pad 51 is opened and the electrode 52 is exposed. When the electrode 52 is exposed, as will be described with reference to FIG. 16, there is a possibility that flare or the like occurs due to influence of reflection by the electrode 52.

FIG. 16 is an enlarged view of a portion of the electrode 52 of one pad 51, and in FIG. 16, an arrow represents incident light or reflected light. In FIG. 16, there is a possibility that incident light incident from an upper left diagonal direction is reflected by the electrode 52, and the reflected light hits a side surface of the semiconductor substrate 80 (a side surface of the pad 51) and is further reflected.

As described with reference to FIG. 3, the plurality of pads 51 is disposed around the pixel array unit 3, so that there is a possibility that such reflection occurs in each pad 51. There is a possibility that specular reflection causes intense flare in certain directions at the electrodes 52 of the pad 51.

Thus, as illustrated in FIG. 17, the opening of the pad 51g is processed. Referring to FIG. 17, in a case where the opening of a pad 51g has a quadrangular shape, at least one side thereof is formed in an uneven shape and is formed in a jagged shape. By forming one side of the semiconductor substrate 80 surrounding the pad 51g into an uneven shape, even if the reflected light reflected by the electrode 52 hits the side surface of the pad 51g, it is possible to scatter the reflected light in various directions, and reduce occurrence of flare or the like.

The opening of the pad 51g illustrated in FIG. 17 has been described by exemplifying a case where one side has an uneven shape, but it is also possible to have a configuration in which two, three, or four sides of four sides of the opening have uneven shapes.

According to an imaging element 1g including such a pad 51g having an uneven shape in the opening, even if specular reflection occurs by the electrode 52 of the pad 51g, the reflected light can be scattered, and occurrence of flare can be reduced.

The seventh embodiment can be implemented in combination with any one or more of the first to sixth embodiments.

### Configuration Example of Imaging Element According to Eighth Embodiment

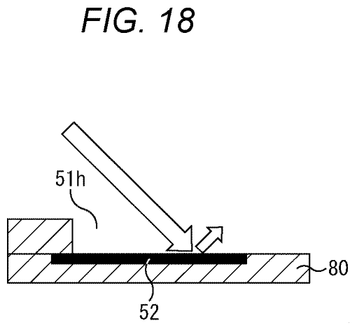

FIG. 18 is a diagram illustrating a cross-sectional configuration example of a pad 51h provided in an imaging element 1h in an eighth embodiment.

The pad 51h illustrated in FIG. 18 has a shape in which at least one side surface of the four side surfaces surrounding the pad 51h is not formed. The pad 51h illustrated in FIG. 18 has a shape in which the side wall on the right side in the figure is removed. In other words, the right side of the pad 51h illustrated in FIG. 18 has no side wall, and is in an opened state. With the shape in which the side wall (semiconductor substrate 80) on the right side of the pad 51h is removed, light reflected by the electrode 52 escapes without being reflected by the semiconductor substrate 80 because there is no side wall of the semiconductor substrate 80 as indicated by an arrow in FIG. 18.

The side wall of the semiconductor substrate 80 formed in the opened state is a side wall at a position away from the pixel array unit 3. The example illustrated in FIG. 18 has a configuration in which the side wall on the right side in the figure is opened, and in this case, the pixel array unit 3 (not illustrated) is located on the left side in the figure.

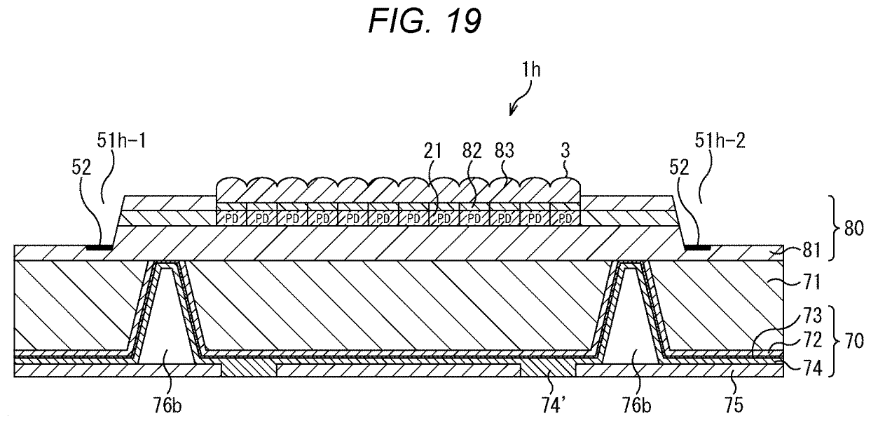

FIG. 19 is a diagram illustrating a cross-sectional configuration example of the imaging element 1h including the pad 51h illustrated in FIG. 18. The pixel array unit 3 is formed in a central portion of the imaging element 1h. The pad 51h is provided on each of the left side and the right side of the pixel array unit 3 in the figure.

Referring to a pad 51h-1 illustrated on the left side in the figure, the pixel array unit 3 is located on the right side with respect to the pad 51h-1. The side wall of the semiconductor substrate 80 corresponding to a side of the pad 51h-1 located on the left side in the figure is opened. The opened side on the left side of the pad 51h-1 is a side located at the farthest position from the pixel array unit 3.

Referring to a pad 51h-2 illustrated on the right side in the figure, the pixel array unit 3 is located on the left side with respect to the pad 51h-2. The side wall of the semiconductor substrate 80 corresponding to a side of the pad 51h-2 located on the right side in the figure is opened. The opened side on the right side of the pad 51h-2 is a side located at the farthest position from the pixel array unit 3.

The opening of the pad 51h illustrated in FIGS. 18 and 19 has been described by exemplifying a case where the pad has a shape in which the side wall of one side is opened, but the side wall of two, three, or four sides of the opening may be opened.

The fact that the side wall surrounding the pad 51h is opened includes that a shape is made in which there is no side wall as illustrated in FIGS. 18 and 19, in other words, a shape in which there is no semiconductor substrate 80. Furthermore, the fact that the side wall surrounding the pad 51h is opened includes a case where the side wall of the semiconductor substrate 80 is at a position away from a predetermined side of the electrode 52 of the pad 51h by a predetermined distance or more. The predetermined distance can be a distance at which the reflected light reflected by the electrode 52 does not hit (a distance at which influence by the reflected light does not occur).

As described above, with a configuration in which at least the side wall of the semiconductor substrate 80 located on one side of the four sides surrounding the pad 51h is opened, occurrence of flare can be reduced.

The eighth embodiment can be implemented in combination with any one or more of the first to seventh embodiments.

The seventh embodiment and the eighth embodiment can be combined to have a configuration in which the side walls of one to three sides among the four side walls surrounding the pad 51 have uneven shapes and the side walls of one to three sides are removed.

### Configuration Example of Imaging Element According to Ninth Embodiment

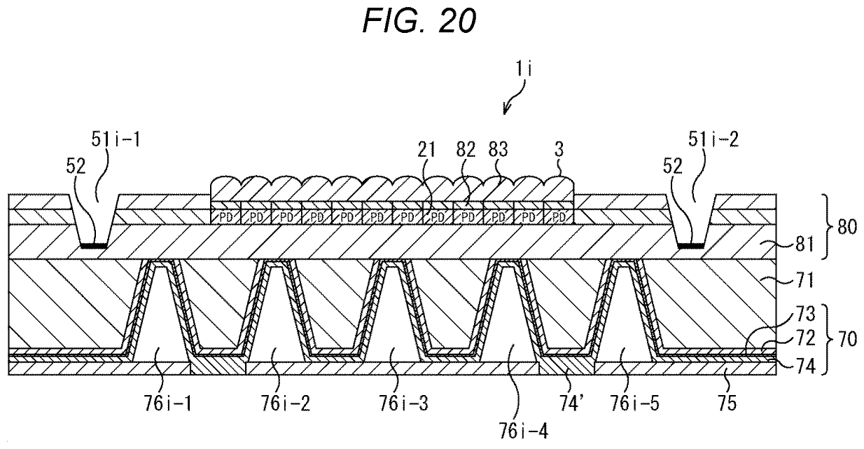

FIG. 20 is a diagram illustrating a cross-sectional configuration example of an imaging element li according to a ninth embodiment. The imaging element li illustrated in FIG. 20 is different from the above-described embodiments in that a plurality of the through electrodes 76 is formed in the support substrate 71 on the lower side of the pixel array unit 3, and the other points are similar.

In the imaging element li illustrated in FIG. 20, five through electrodes 76i-1 to 761-5 are provided in cross-sectional view. The plurality of electrodes 76 may be provided not only in the vicinity of the pad 51 but also in the support substrate 71 other than in the vicinity.

In a case where the imaging element li includes a plurality of through electrodes 76i, the through electrode 76 of the imaging element 1 to which the first to eighth embodiments are applied is a through electrode 76i located closest to the pad 51. For example, in the example illustrated in FIG. 20, the through electrode 761-1 is located in the vicinity of the pad 511-1, and the configuration of the through electrode 76 according to the first to eighth embodiments is applied to the through electrode 761-1.

In the example illustrated in FIG. 20, for example, there is a relationship in which the pad 51i-1 and the through electrode 76i-1 are located in the vicinity of each other, and there is a relationship in which the second embodiment is applied to the pad 51i-1 and the through electrode 761-1, and the pad 51i-1 and the through electrode 761-1 are disposed at positions shifted from each other.

The ninth embodiment can be implemented in combination with any one or more of the first to eighth embodiments.

Note that, in the first to ninth embodiments, as an example, a case has been described where the through electrode 76 is located inside (located on the pixel array unit 3 side) in a case where the through electrode 76 is located at a position shifted from the pad 51. In the first to ninth embodiments, it is possible to have a configuration in which the through electrode 76 is located on the outer side (located in a direction away from the pixel array unit 3) in a case where the through electrode 76 is located at a position shifted from the pad 51, and such a configuration is also within the scope of application of the present technology.

### Configuration Example of Imaging Element According to Tenth Embodiment

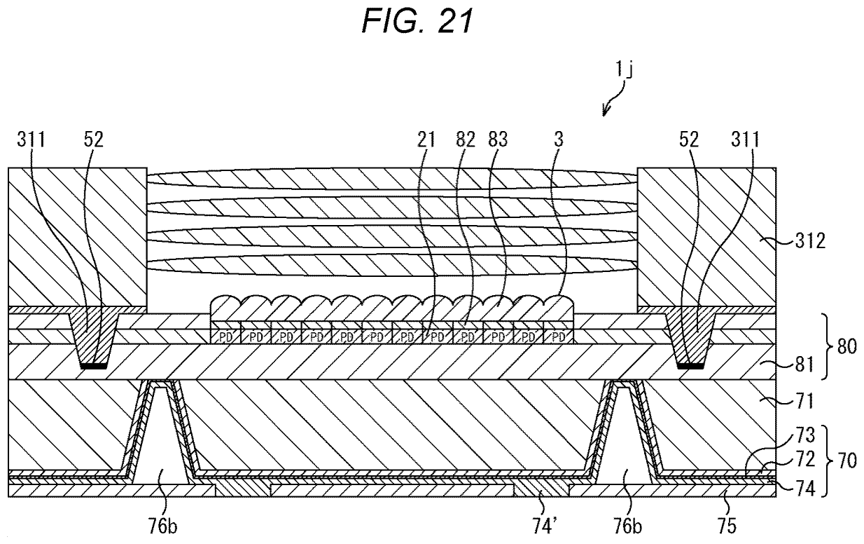

FIG. 21 is a diagram illustrating a cross-sectional configuration example of an imaging element 1j according to a tenth embodiment. The imaging element 1j illustrated in FIG. 21 is different from the above-described embodiments in that it has a configuration in which a lens barrel 312 is mounted.

A plurality of lenses (in the example illustrated in FIG. 21, three lenses) is incorporated inside the lens barrel 312, and the lens barrel 312 is configured to hold the lenses. The lens barrel 312 can be included in an actuator (not illustrated). It is possible to have a configuration in which an actuator is included, and the lens barrel 312 can move in a vertical direction in the figure, and auto-focus (AF) can be performed.

The lens barrel 312 is connected to the imaging element 1 with the base 311 interposed therebetween. The base 311 is formed also in the pad 51, and for example, formation is performed by filling the pad 51 with a predetermined material.

It is possible to have a configuration in which the pad 51 (electrode 52) is provided for inspection at the time of manufacturing, and is protected by the base 311 without exposing the electrode 52 in a case where it is not necessary after manufacturing (after inspection). With such a configuration, the base 311 can be formed on the pad 51, so that it is possible to have a configuration in which the imaging element 1j can be downsized, and the electrode 52 is protected.

The example illustrated in FIG. 21 illustrates an example in which the lens barrel 312 is mounted on the imaging element 1b according to the second embodiment. However, it is also possible to have a configuration in which the lens barrel 312 is mounted on any one of the first to ninth imaging elements 1. The tenth embodiment can be implemented in combination with any one or more of the first to ninth embodiments.

### Configuration Example of Imaging Element According to Eleventh Embodiment

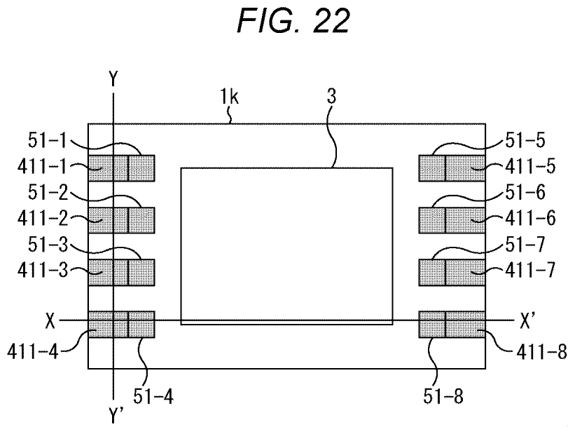

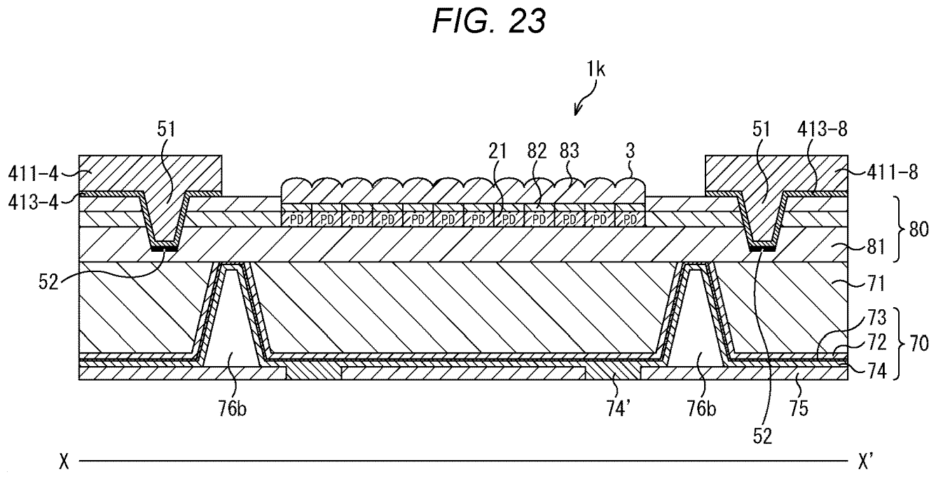

FIG. 22 is a diagram illustrating a planar configuration example of an imaging element 1k according to an eleventh embodiment, and FIG. 23 is a diagram illustrating a cross-sectional configuration example at a line segment X-X′ in FIG. 22. The imaging element 1k illustrated in FIGS. 22 and 23 is different from the first to tenth embodiments in that a lead-out wiring line 411 is provided at a portion of the electrode 52, and the other points are basically similar.

FIG. 22 is a diagram illustrating a planar configuration example when viewed from the light incident surface side of the imaging element 1k, and the configuration is basically the same as the planar configuration example illustrated in FIG. 3. The pixel array unit 3 is provided in a central region of the pixel 2. The pads 51-1 to 51-8 are provided in the outer peripheral region of the pixel array unit 3.

The pads 51-1 to 51-4 are provided on the left side in the figure of the pixel array unit 3, and the pads 51-5 to 51-8 are provided on the right side in the figure. Lead-out wiring lines 411-1 to 411-8 are provided to the pads 51-1 to 51-8, respectively.

The lead-out wiring line 411 covers the pad 51 and is formed up to the side surface of the imaging element 1. Referring to the cross-sectional configuration example in FIG. 23, the lead-out wiring line 411-4 is formed such that the pad 51-4 is filled with a material, and moreover, is formed in a quadrangular shape in a cross-sectional view also on the back surface (light incident surface) of the semiconductor substrate 80. The left side in the figure of the lead-out wiring line 411-4 corresponds to the side surface of the imaging element 1 and is formed in an exposed state.

Similarly to the lead-out wiring line 411-4, the lead-out wiring line 411-8 formed such that the pad 51-8 is filled with a material, and moreover, is formed in a quadrangular shape in a cross-sectional view also on the back surface (light incident surface) of the semiconductor substrate 80. The right side in the figure of the lead-out wiring line 411-8 corresponds to the side surface of the imaging element 1 and is formed in an exposed state.

The lead-out wiring lines 411-1 to 411-8 also have the same configuration as the lead-out wiring lines 411-4 and 411-8. A barrier metal 413 is formed on an interface between the lead-out wiring line 411 and the semiconductor substrate 80 and a side surface in the pad 51.

The electrode 52 and the lead-out wiring line 411 formed in the pad 51 are formed in a conductive state. Since the electrode 52 is connected to a circuit in the imaging element 1k, the lead-out wiring line 411 is connected to the circuit in the imaging element 1k via the electrode 52.

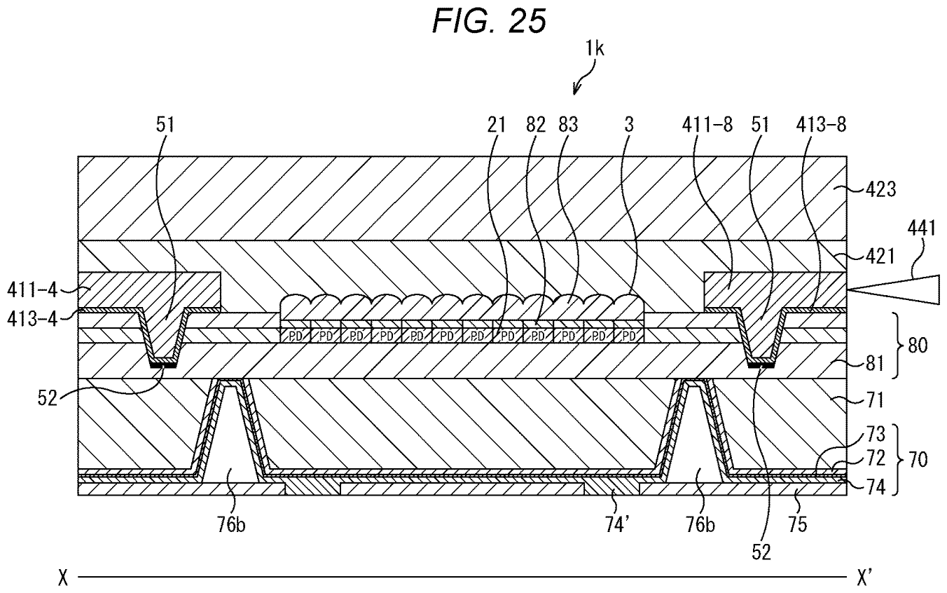

The description will be continued using the lead-out wiring line 411-4 as an example. In the example illustrated in FIG. 23, the lead-out wiring line 411-4 is in a state where the side surface and the upper surface are exposed in a quadrangular shape portion formed on the back surface side of the semiconductor substrate 80. In this case, the inspection needle 441 (FIG. 25) can be dropped on any exposed surface to execute a predetermined inspection.

The lead-out wiring line 411 includes metal having high conductivity. As the material of the lead-out wiring line 411, for example, copper (Cu), silver (Ag), gold (Au), aluminum (Al), or the like can be used. By providing the lead-out wiring line 411 and by forming the lead-out wiring line 411 with a material having high thermal conductivity such as metal, it is possible to release heat generated in the imaging element 1 to the outside of the imaging element 1.

The barrier metal 413 is provided to prevent leakage of metal (lead-out wiring line 411) into the insulating film, and for example, metal can be used such as titanium (Ti), titanium nitride (TiN), tantalum (Ta), tantalum nitride (TaN), or ruthenium (Ru).

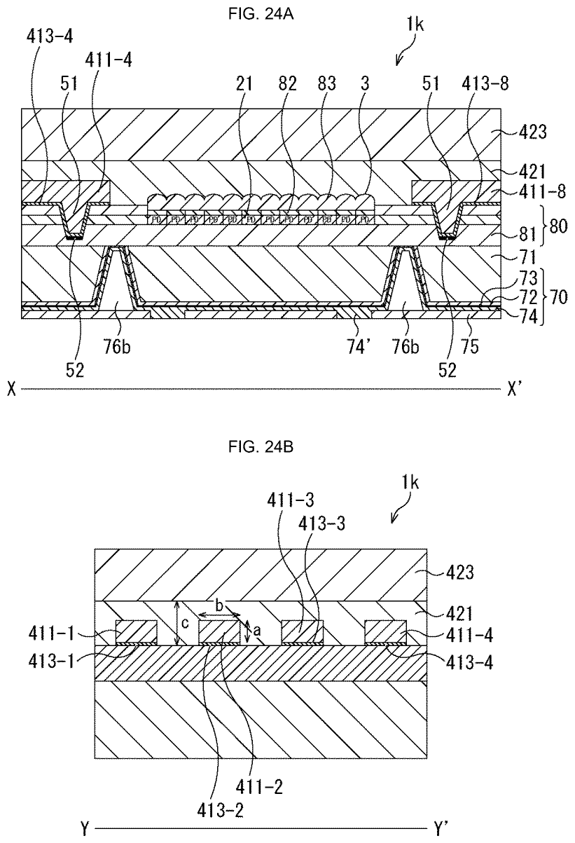

The imaging element 1k illustrated in FIG. 23 illustrates a case of having a glassless structure in which glass or the like is not stacked, but a configuration may be adopted in which a glass substrate is stacked, as illustrated in FIG. 24. A of FIG. 24 illustrates a cross-sectional configuration example of the imaging element 1k at a line segment X-X′ of FIG. 22, and B of FIG. 24 illustrates a cross-sectional configuration example of the imaging element 1k at a line segment Y-Y′ of FIG. 22.

In the imaging element 1k illustrated in FIG. 24, a glass substrate 423 is disposed on the imaging element 1k illustrated in FIG. 23 with a bonding resin 421 interposed therebetween. The lead-out wiring line 411 is covered with the bonding resin 421, but the lead-out wiring line 411 on a surface corresponding to a side surface of the imaging element 1k is in an exposed state. As described above, due to the fact that the lead-out wiring line 411 is formed in a partially exposed state, even in the imaging element 1k after the glass substrate 423 is stacked and singulated as illustrated in FIG. 25, it is possible to bring the needle 441 into contact with the lead-out wiring line 411 and perform a predetermined inspection on the imaging element 1k.

There is a possibility that characteristics of the imaging element 1k change before and after the bonding resin 421 and the glass substrate 423 are stacked. Even in such a case, by providing the lead-out wiring line 411, it is possible to perform an inspection using the lead-out wiring line 411 at both a time point before the bonding resin 421 and the glass substrate 423 are stacked and a time point after the stack.

Referring to B of FIG. 24, in a cross-sectional view of the imaging element 1k, the exposed lead-out wiring line 411 is formed in a quadrangular shape having a predetermined size. On the side surface of the imaging element 1k, the lead-out wiring line 411 is formed so as to have an exposed portion with the quadrangular shape having the predetermined size. Since the needle 441 is brought into contact with this exposed region, the exposed portion of the lead-out wiring line 411 is formed with a size that allows the needle 441 to easily come into contact with the exposed region.

As illustrated in B of FIG. 24, the thickness in the longitudinal direction of the exposed portion of the lead-out wiring line 411 is defined as a thickness a, the width in the lateral direction is defined as a width b, and the thickness of the bonding resin 421 is defined as a thickness c. In a case where the thickness c of the bonding resin is, for example, 50 μm, the lead-out wiring line 411 can be formed to have the thickness a of 30 to 50 μm and the width b of 30 to 100 μm. The size of the exposed portion of the lead-out wiring line 411 can be appropriately changed according to the configuration of the entire imaging element 1k (chip), the diameter of the tip of the needle 441 (FIG. 25) at the time of inspection, the alignment accuracy of a device, and the like, and the numerical values described here are merely examples, and do not represent limitations.

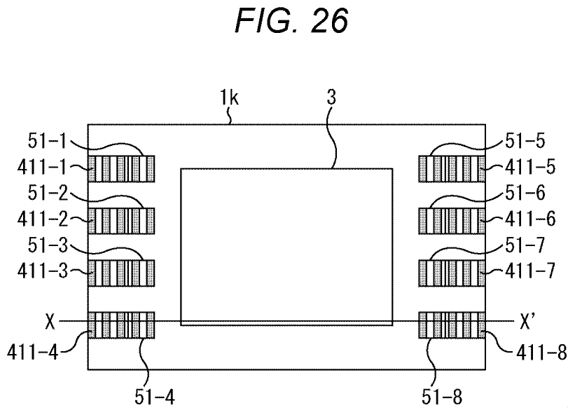

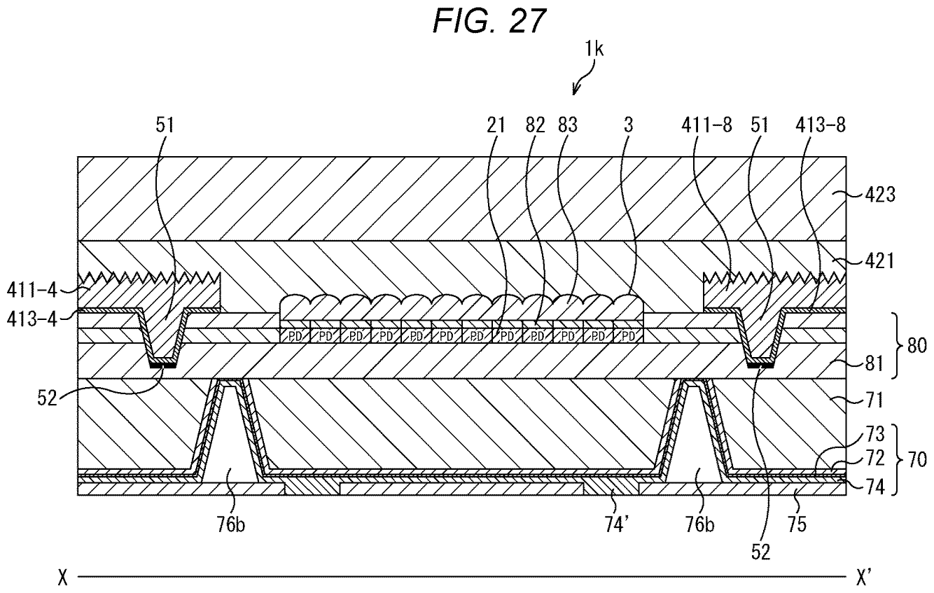

In a portion where the lead-out wiring line 411 is provided, the thickness of the bonding resin 421 is reduced. In other words, an amount of the bonding resin 421 between the lead-out wiring line 411 and the glass substrate 423 is smaller than that between a portion where there is no lead-out wiring line 411 and the glass substrate 423. In a case where there is a possibility that adhesive force of the portion decreases due to the small thickness of the bonding resin 421, the lead-out wiring line 411 can also be formed as illustrated in FIGS. 26 and 27.

FIG. 26 is a diagram illustrating another planar configuration example of the imaging element 1k, and FIG. 27 is a diagram illustrating another cross-sectional configuration example of the imaging element 1k. The lead-out wiring line 411 illustrated in FIGS. 26 and 27 has unevenness on a surface that is a surface on a side where the glass substrate 423 is stacked, and is a surface in contact with the bonding resin 421. By providing the lead-out wiring line 411 with unevenness, it is possible to increase an area to be bonded to the bonding resin 421. With an increase in an area where the lead-out wiring line 411 and the bonding resin 421 are in contact with each other, the adhesive force is improved, and a structure can be obtained in which the glass substrate 423 is hardly peeled off.

### Regarding manufacturing of Imaging Element 1k

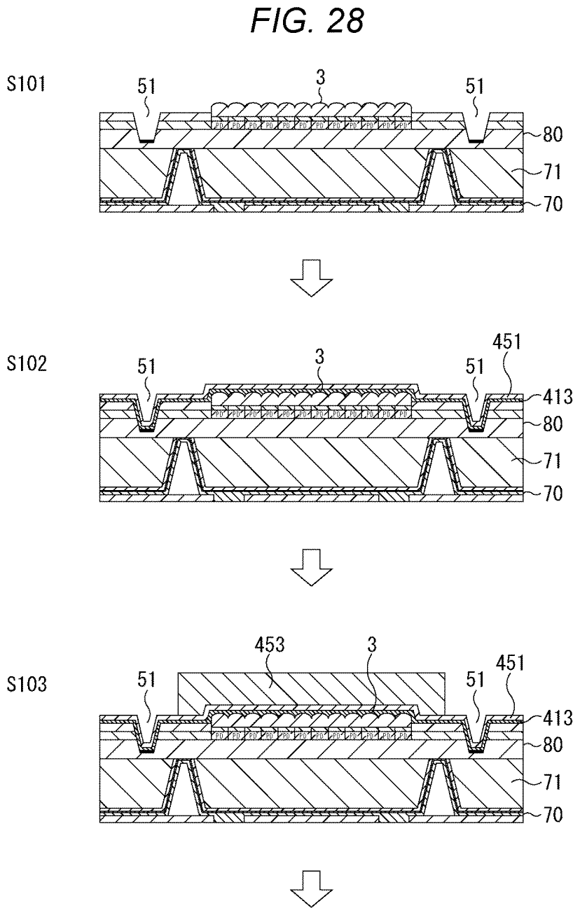

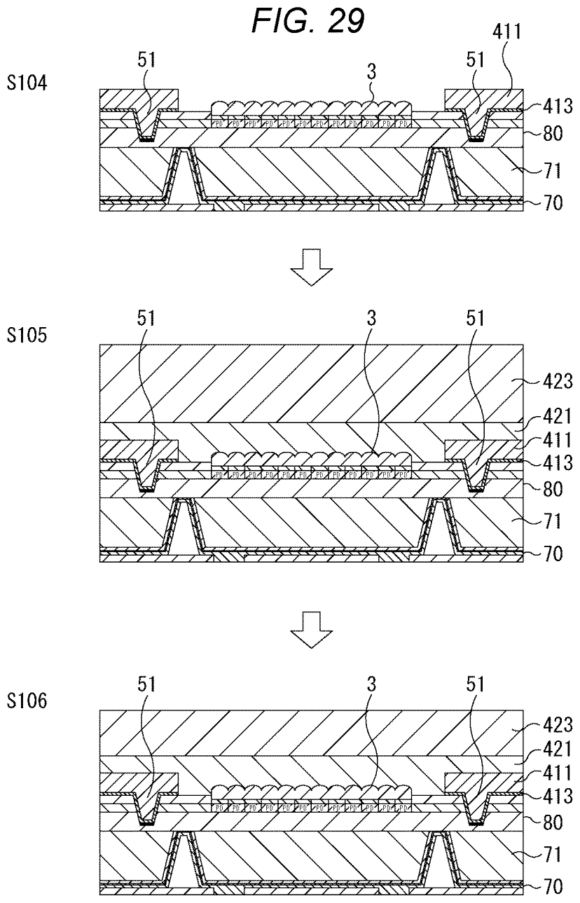

Manufacturing of the imaging element 1k illustrated in FIG. 24 will be described with reference to FIGS. 28 and 29.

In a process S101, the imaging element 1k is prepared on which the pad 51 and the through electrode 76 are formed. The imaging element 1k prepared in the process S101 is the imaging element 1b illustrated in FIG. 5, and is the imaging element 1k manufactured in the processes S11 to S15 illustrated in FIG. 8. In the process S101, the imaging element 1k is in a state before being singulated, that is, in a wafer state.

Since the imaging element 1k in the process S101 is in a state where the pad 51 is opened and the electrode 52 is provided, a predetermined inspection can be executed by dropping the needle 441 on the electrode 52.

In a process S102, the barrier metal 413 and a seed metal 451 for plating are deposited by sputtering on a surface on which the pad 51 is opened (a surface on the upper side in the figure).

In a process S103, a photoresist film 453 is formed on a portion not to be plated, in other words, a portion where the lead-out wiring line 411 is not to be formed. After the photoresist film 453 is formed, electrolytic plating is performed by a semi-additive method to form a portion to be the lead-out wiring line 411.

In a process S104 (FIG. 29), the photoresist film 453 is removed, and excess of the barrier metal 413 and the seed metal 451 are removed by using a predetermined chemical solution. Since the imaging element 1k in the process S104 is in a state where the lead-out wiring line 411 connected to the electrode 52 is formed, a predetermined inspection can be executed by dropping the needle 441 on the lead-out wiring line 411.

In a process S105, the bonding resin 421 is applied, and the glass substrate 423 is bonded thereon.

In a process S106, the glass substrate 423 is polished to a desired thickness. Thereafter, singulation is executed to manufacture the imaging element 1k.

Also in the imaging element 1k singulated, since the lead-out wiring line 411 is exposed on a predetermined side surface of the imaging element 1k, a predetermined inspection can be executed by dropping the needle 441 on the lead-out wiring line 411 exposed.

By providing the lead-out wiring line 411, it is possible to perform inspection using the lead-out wiring line 411 before and after singulation. By provision of the lead-out wiring line 411, the imaging element 1k has a configuration in which heat in the imaging element 1k can be released to the outside through the lead-out wiring line 411, and heat dissipation performance can be improved.

The lead-out wiring line 411 can be used not only at the time of inspection but also as a terminal connected to another circuit, another imaging element, or the like.

### Another Configuration of Lead-Out Wiring Line

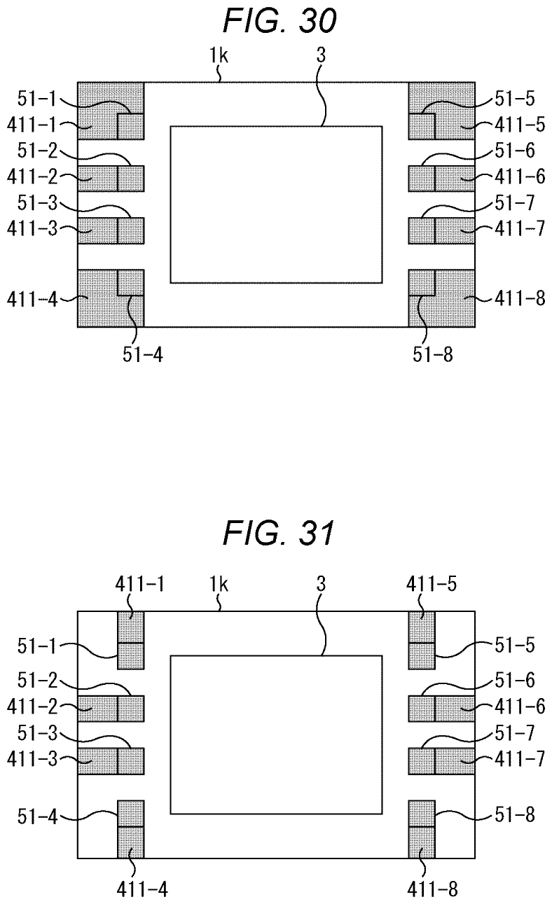

FIG. 30 is a diagram illustrating another configuration example of the lead-out wiring line 411. The configuration is basically similar to the lead-out wiring lines 411-1 to 411-8 illustrated in FIG. 22, but the configuration of the lead-out wiring lines 411 located at corner portions is different.

The lead-out wiring line 411-1 located at the upper left in the figure, the lead-out wiring line 411-4 located at the lower left, the lead-out wiring line 411-5 located at the upper right, and the lead-out wiring line 411-8 located at the lower right are formed to be larger than the other lead-out wiring lines 411, and are formed in a state where two side surfaces are exposed. For example, the lead-out wiring line 411-1 located at the upper left in the figure is formed in a state where the left side surface and the upper side surface in the figure are exposed.

As described above, with a configuration in which the lead-out wiring lines 411 located at the four corners of the imaging element 1k are formed in a state where the two surfaces are exposed, the heat dissipation performance can be further improved. Furthermore, since the number of surfaces with which the needle 441 at the time of inspection is brought into contact is two, it is possible to increase a degree of freedom regarding a position of the needle 441 at the time of inspection.

FIG. 31 is a diagram illustrating another configuration example of the lead-out wiring line 411. The configuration is basically similar to the lead-out wiring lines 411-1 to 411-8 illustrated in FIG. 22, but is different in that the lead-out wiring lines 411 located at corner portions are provided to face in different directions.

The lead-out wiring line 411-1 located at the upper left in the figure is formed to face upward in the figure, and is formed in a state where the upper surface is exposed. The lead-out wiring line 411-2 and the lead-out wiring line 411-3 are formed to face leftward in the figure, and are formed in a state where the left side surfaces are exposed. The lead-out wiring line 411-4 located at the lower left in the figure is formed to face downward in the figure, and is formed in a state where the lower surface is exposed.

With respect to the lead-out wiring line 411-1 and the lead-out wiring line 411-4, the lead-out wiring line 411-2 and the lead-out wiring line 411-3 are disposed with an angle formed by 90 degrees.

The lead-out wiring line 411-5 located at the upper right in the figure is formed to face upward in the figure, and is formed in a state where the upper surface is exposed. The lead-out wiring line 411-6 and the lead-out wiring line 411-7 are formed to face rightward in the figure, and are formed in a state where the right side surfaces are exposed. The lead-out wiring line 411-8 located at the lower right in the figure is formed to face downward in the figure, and is formed in a state where the lower surface is exposed.

With respect to the lead-out wiring line 411-5 and the lead-out wiring line 411-8, the lead-out wiring line 411-6 and the lead-out wiring line 411-7 are disposed with an angle formed by 90 degrees.

Although the configuration of an example of the lead-out wiring line 411 is illustrated in FIGS. 30 and 31, a configuration not illustrated can also be applied to the present technology.

### Still Another Configuration of Imaging Element 1k

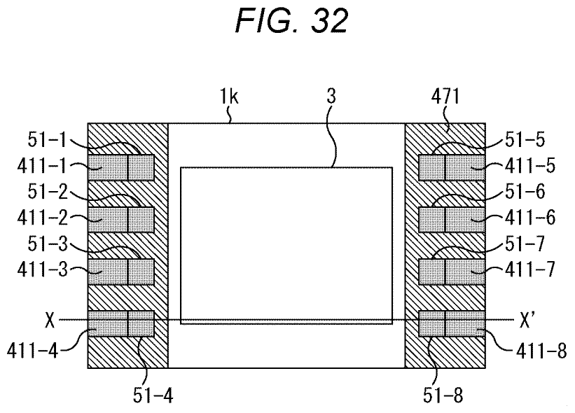

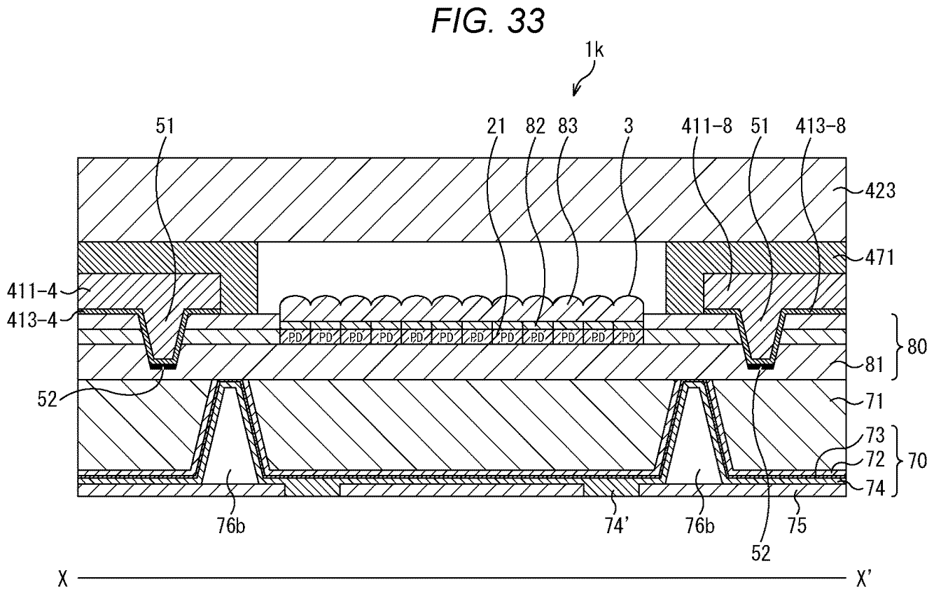

FIGS. 32 and 33 are diagrams for explaining still another configuration of the imaging element 1k. The imaging element 1k illustrated in FIGS. 32 and 33 has a configuration in which the glass substrate is disposed on the imaging element 1 similarly to the imaging element 1k illustrated in FIG. 24, but illustrates a case of the imaging element 1 having a cavity structure without the bonding resin 421.

In the imaging element 1k, the glass substrate 423 is disposed with a base 471 interposed therebetween. The base 471 is formed so as to cover the lead-out wiring line 411, but a portion exposed on the side surface of the imaging element 1k is formed so that the exposed state is maintained. Since there is no base 471 on the pixel region, in other words, since the base 471 is formed so as to surround the pixel region, the pixel region can have a cavity structure as a void.

Even in the case of such a configuration, in the imaging element 1k singulated, the lead-out wiring line 411 is exposed on the predetermined side surface of the imaging element 1k, so that a predetermined inspection can be executed by dropping the needle 441 on the lead-out wiring line 411 exposed.

By providing the lead-out wiring line 411, it is possible to perform inspection before and after singulation. By provision of the lead-out wiring line 411, the imaging element 1k has a configuration in which heat in the imaging element 1k can be released to the outside through the lead-out wiring line 411, and heat dissipation performance can be improved.

The lead-out wiring line 411 can be used not only at the time of inspection but also as a terminal connected to another circuit, another imaging element, or the like.

As a shape of the lead-out wiring line 411, the shapes illustrated in FIGS. 30 and 31 can also be applied.

The twelfth embodiment can be applied in combination with any one or more of the first to tenth embodiments. That is, it is possible to have a configuration in which the lead-out wiring line 411 is provided in any one of the imaging elements 1 according to the first to tenth embodiments.

### Configuration Example of Imaging Element According to Twelfth Embodiment

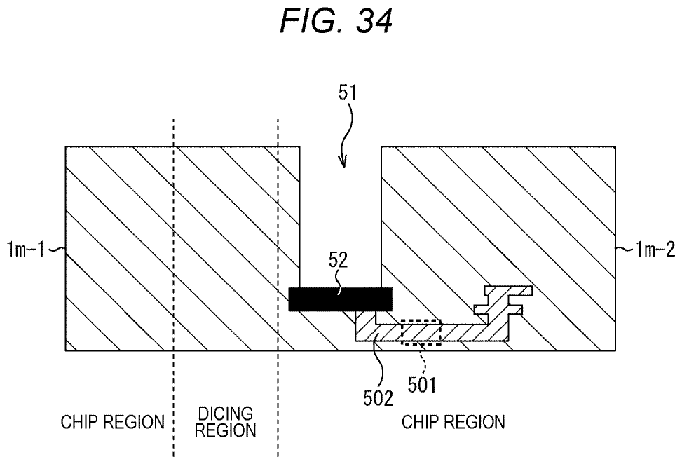

FIG. 34 is a diagram illustrating a cross-sectional configuration example of an imaging element 1m according to a twelfth embodiment. FIG. 34 is an enlarged and simplified diagram of a portion of the pad 51 of the imaging element 1m before singulation. Note that, regarding the configuration not illustrated of the imaging element 1m, the configurations of the first to eleventh imaging elements can be appropriately applied.

FIG. 34 illustrates an imaging elements 1m-1 and an imaging element 1m-2 adjacent to each other before singulation. A dicing region is provided between the imaging element 1m-1 and the imaging element 1m-2 before singulation. Dicing is performed in the dicing region, whereby the imaging element 1m-1 and the imaging element 1m-2 are singulated. In the figure, the dicing region is provided between a chip region and a chip region, and the chip regions each includes the imaging element 1m and also includes a guard ring (not illustrated).

The imaging element 1m-2 is provided with the pad 51, and the pad 51 is provided with the electrode 52. A wiring line 502 connected to a circuit in the imaging element 1m-2 is connected to the electrode 52. A fuse 501 is provided in a part of the wiring line 502. The fuse 501 is provided to electrically disconnect the electrode 52 from the circuit in the imaging element 1m-2. The circuit is, for example, a circuit that processes a signal from the pixel array unit 3.

Even after singulation, the electrode 52 and the circuit in the imaging element 1m-2 are connected to each other by the wiring line 502. In order to prevent the circuit in the imaging element 1m-2 from being affected in a case where a phenomenon that causes an adverse effect on the circuit occurs in the electrode 52 exposed, a mechanism may be provided in which the fuse 501 is blown when such a phenomenon occurs. Furthermore, a configuration may be adopted in which, after the singulation, the fuse 501 is blown, and electrical connection between the electrode 52 and the circuit is disconnected.

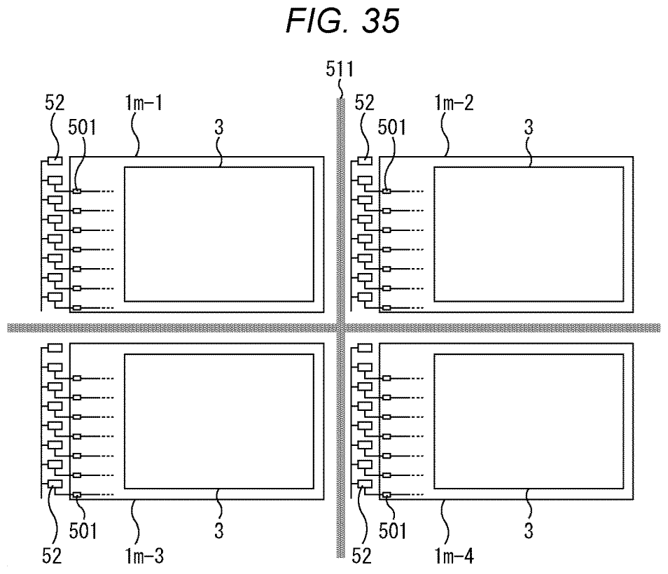

As described above, in a case where the pad 51 remains and singulated, dicing is performed at a position as illustrated in FIG. 35. FIG. 35 illustrates 2×2 imaging elements 1m-1 to 1m-4 formed on a wafer. Between the imaging element 1m-1 and the imaging element 1m-2 and between the imaging element 1m-3 and the imaging element 1m-4 are diced along a dicing line 511 in the longitudinal direction in the figure. Between the imaging element 1m-1 and the imaging element 1m-3 and between the imaging element 1m-2 and the imaging element 1m-4 are diced along the dicing line 511 in the lateral direction in the figure.

Since the dicing line 511 is set outside the pad 51 of the imaging element 1m-2, the imaging element 1m-2 after singulation is singulated in a state where the pad 51 and the electrode 52 remain and the fuse 501 in the chip also remains.

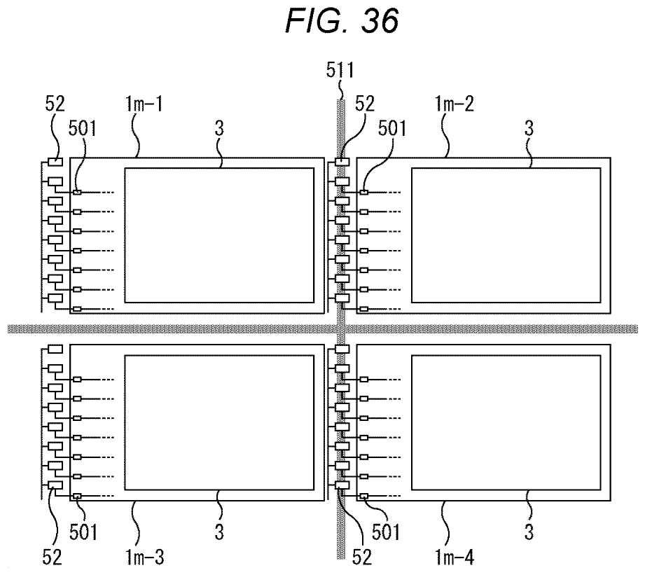

As illustrated in FIG. 36, the dicing line 511 may be set at a position of the pad 51. In the example illustrated in FIG. 36, dicing is performed along the dicing line 511 in the longitudinal direction in the figure between the imaging element 1m-1 and the imaging element 1m-2 and between the imaging element 1m-3 and the imaging element 1m-4, and the dicing line 511 is set on the pad 51 (electrode 52).

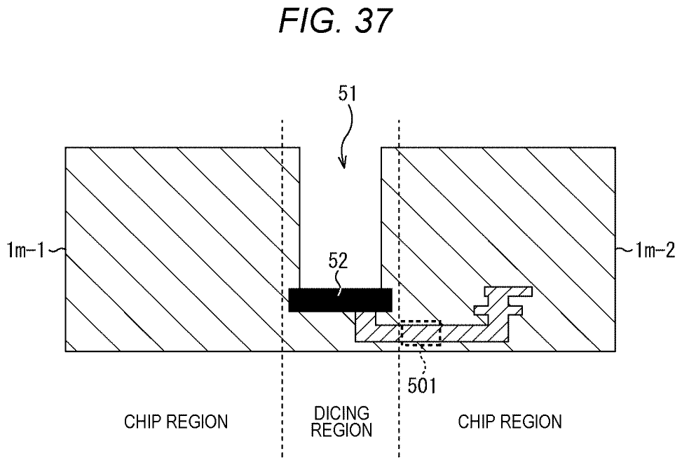

FIG. 37 is an enlarged view of a portion of the pad 51 of the imaging element 1m before singulation in a case where the dicing line 511 is set on the pad 51.

FIG. 37 illustrates the imaging element 1m-1 and the imaging element 1m-2 adjacent to each other before singulation. A dicing region is provided between the imaging element 1m-1 and the imaging element 1m-2 before singulation. Since the dicing line 511 is set in the dicing region, the imaging element 1m-2 after being singulated is in a state where the wiring line 502 is exposed to the side surface and the fuse 501 is inside.

For example, in a case where the dicing width is narrow, a part of the electrode 52 may remain or a part of the wiring line 502 may remain on the side surface of the imaging element 1m after singulation.

The fuse 501 may be configured to be blown by heat or the like during dicing. It is possible to make the wiring line 502 and the circuit electrically disconnected from each other due to blowing of the fuse 501, and prevent the circuit from being affected in a case where a phenomenon that adversely affects the circuit occurs in the wiring line 502 exposed.

By performing singulation at the position of the pad 51, it is possible to remove the portion of the pad 51, so that the imaging element 1m after singulation can be downsized.

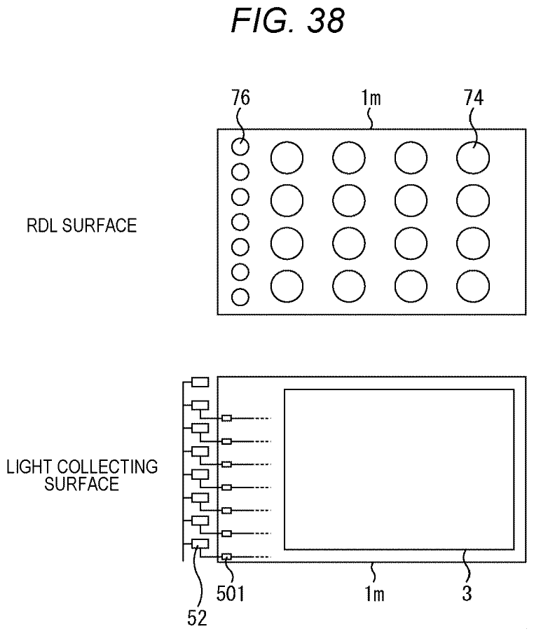

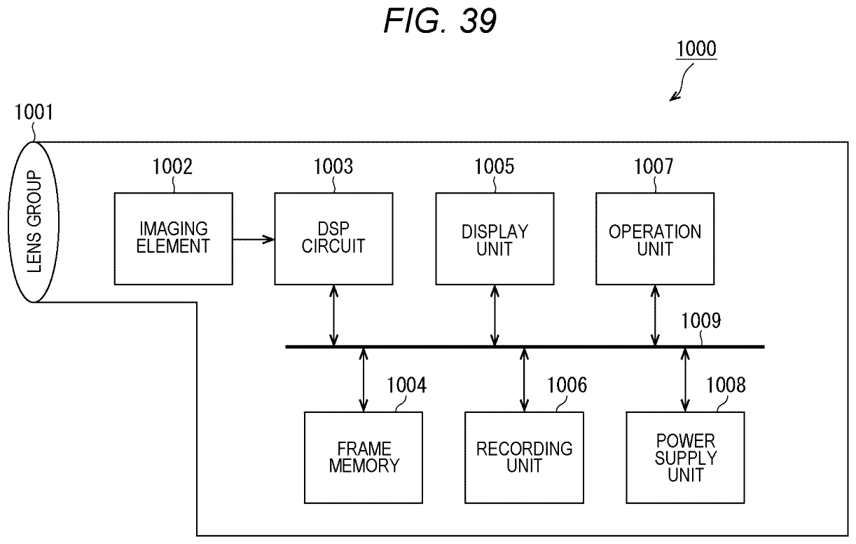

FIG. 38 illustrates a planar configuration example of the imaging element 1m after singulation. The upper diagram in FIG. 38 illustrates a planar configuration example on a rewiring line (redistribution layer (RDL)) surface side, and the lower diagram illustrates a planar configuration example on a light collecting surface side.

A plurality of the lands 74 and a plurality of the through electrodes 76 are provided on the RDL surface. The light collecting surface is provided with the pixel array unit 3 and the fuse 501 on the left side in the figure of the pixel array unit 3. FIG. 38 also illustrates the electrode 52 connected to the fuse 501, but the electrode 52 is not present after singulation and thus is illustrated outside the imaging element 1m. As illustrated in FIG. 38, the through electrode 76 and the electrode 52 (pad 51) are provided at positions shifted from each other.

An inspection using the pad 51 can be performed before singulation, and an inspection can be performed using the land 74 after singulation. A configuration may be adopted in which an insulating film, a moisture-proof film, or the like is formed on the side surface of the imaging element 1m after singulation.

The configuration in which the fuse 501 is provided can also be applied to the imaging element 1 according to the first to eleventh embodiments. Furthermore, it is also possible to perform dicing with the portion of the pad 51 of the imaging element 1 according to the first to eleventh embodiments as a dicing region to perform singulation.

### Application Example to Electronic Device

The present technology can be applied to all electronic devices using an imaging element in an image capturing unit (photoelectric conversion unit), such as an imaging device like a digital still camera or a video camera, a mobile terminal device having an imaging function, and a copying machine using the imaging element in an image reading unit. The imaging element may be formed as one chip, or may be in a modular form having an imaging function in which an imaging unit and a signal processing unit or an optical system are packaged together.

FIG. 39 is a block diagram illustrating a configuration example of an imaging device as an electronic device to which the present technology is applied.

An imaging element 1000 in FIG. 39 includes an optical unit 1001 including a lens group and the like, an imaging element (imaging device) 1002, and a digital signal processor (DSP) circuit 1003 that is a camera signal processing circuit. The imaging element 1000 also includes a frame memory 1004, a display unit 1005, a recording unit 1006, an operation unit 1007, and a power supply unit 1008. The DSP circuit 1003, the frame memory 1004, the display unit 1005, the recording unit 1006, the operation unit 1007, and the power supply unit 1008 are connected to one another via a bus line 1009.

The optical unit 1001 captures incident light (image light) from an object, and forms an image on the imaging surface of the imaging element 1002. The imaging element 1002 converts an amount of incident light forming an image on the imaging surface by the optical unit 1001 into an electric signal on a pixel basis, and outputs the electric signal as a pixel signal.

The display unit 1005 includes a flat-panel display such as a liquid crystal display (LCD) or an organic electro luminescence (EL) display, for example, and displays a video image or a still image captured by the imaging element 1002. The recording unit 1006 records the video image or the still image captured by the imaging element 1002 in a recording medium such as a hard disk or a semiconductor memory.

The operation unit 1007 issues operation commands for various functions of the imaging element 1000, being operated by a user. The power supply unit 1008 appropriately supplies various kinds of power that are operating power supplies for the DSP circuit 1003, the frame memory 1004, the display unit 1005, the recording unit 1006, and the operation unit 1007, to these supply targets.

The imaging element 1 according to the first to tenth embodiments can be applied to a part of the imaging device illustrated in FIG. 39.

### Application Example to Endoscopic Surgery System

The technology according to the present disclosure (the present technology) can be applied to various products. For example, the technology according to the present disclosure may be applied to an endoscopic surgery system.

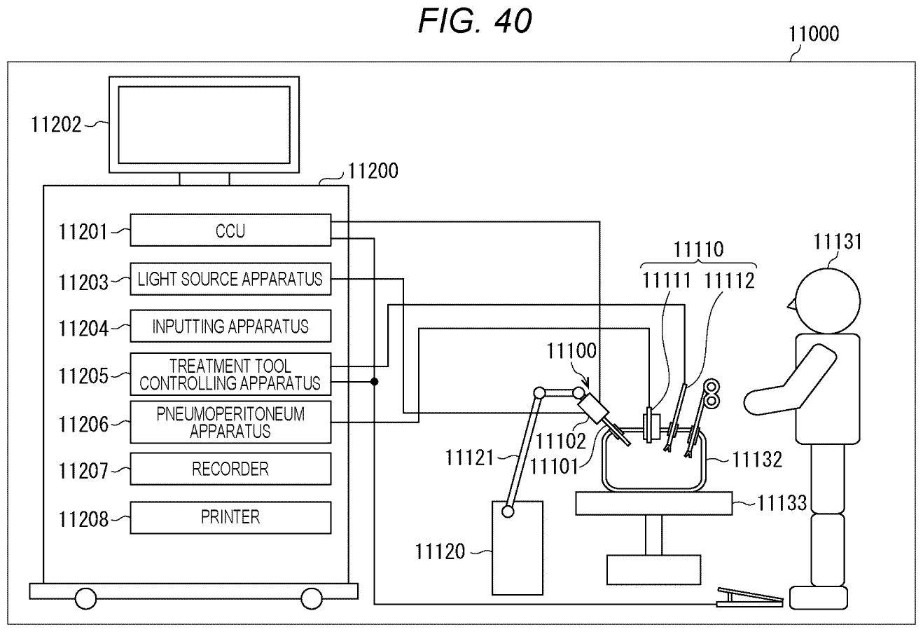

FIG. 40 is a diagram depicting an example of a schematic configuration of an endoscopic surgery system to which the technology according to the present disclosure (the present technology) can be applied.

FIG. 40 depicts a state where a surgeon (medical doctor) 11131 is using an endoscopic surgery system 11000 to perform surgery on a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203.

Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally.

According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

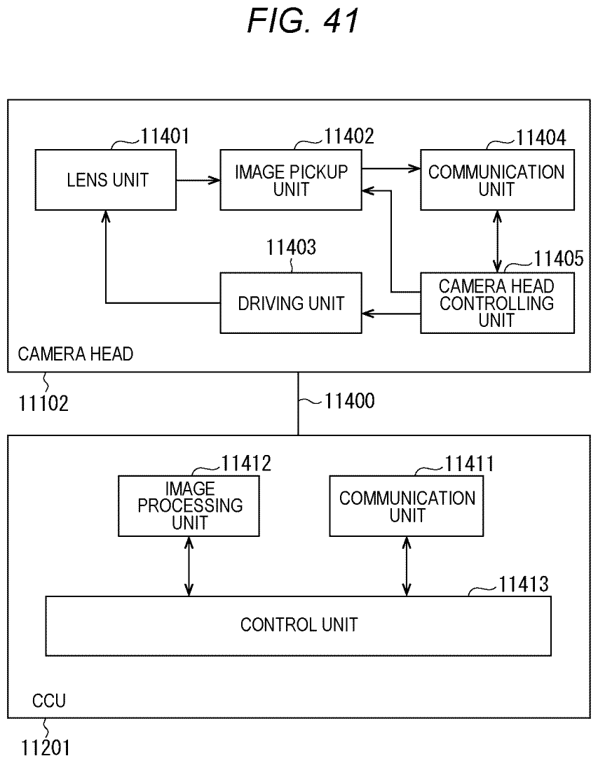

FIG. 41 is a block diagram depicting an example of functional configurations of the camera head 11102 and the CCU 11201 depicted in FIG. 40.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

### Application Example to Mobile Body

The technology according to the present disclosure (the present technology) can be applied to various products. For example, the technology according to the present disclosure may be implemented as a device to be mounted on a mobile body of any kind, such as an automobile, an electric automobile, a hybrid electric automobile, a motorcycle, a bicycle, a personal mobility, an airplane, a drone, a ship, or a robot.

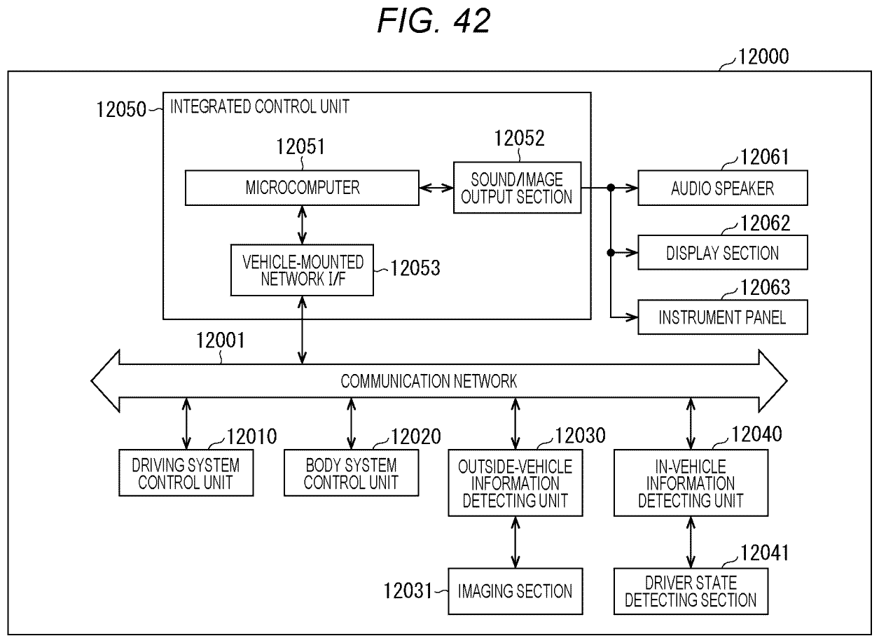

FIG. 42 is a block diagram illustrating an example of schematic configuration of a vehicle control system as an example of a mobile body control system to which the technology according to the present disclosure can be applied.

The vehicle control system 12000 includes a plurality of electronic control units connected to each other via a communication network 12001. In the example illustrated in FIG. 42, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 42, an audio speaker 12061, a display section 12062, and an instrument panel 12063 are exemplified as the output device. The display section 12062 may, for example, include at least one of an on-board display and a head-up display.

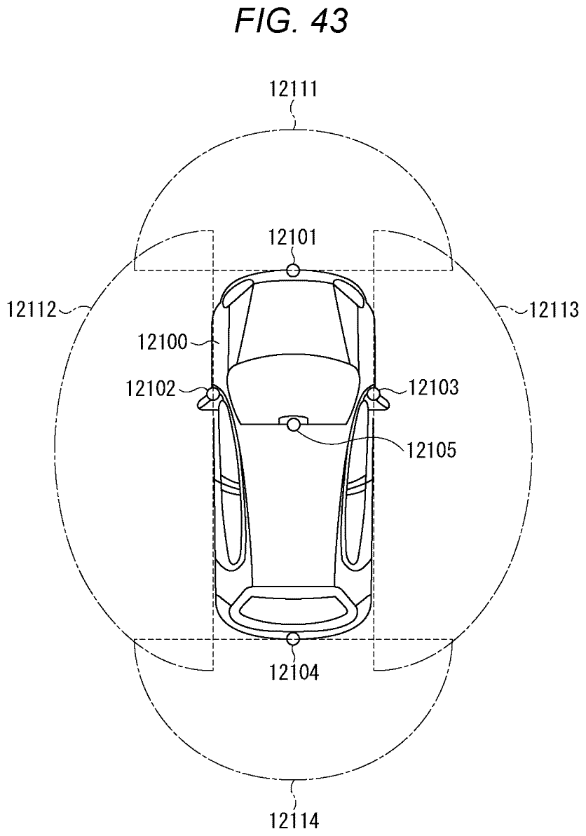

FIG. 43 is a diagram illustrating an example of an installation position of the imaging section 12031.

In FIG. 43, imaging sections 12101, 12102, 12103, 12104, and 12105 are included as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 43 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour) . Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object.

When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the present specification, the system represents the entire device including a plurality of devices.

Note that the effects described in the present specification are merely examples and are not limited, and other effects may be provided.

Note that embodiments of the present technology are not limited to the above-described embodiments, and various changes can be made without departing from the gist of the present technology.

Note that the present technology may also have the following configurations.

(1)

An imaging element including:
a pixel array unit in which pixels each including a photoelectric conversion element are two-dimensionally arranged;
a pad including an opening on a side of a first surface on which the pixel array unit is provided;
an electrode provided in a state of being exposed to the bottom of the pad;
a through electrode including an opening on a second surface on an opposite side from the first surface; and
a rewiring layer stacked on the second surface,
in which
the inside of the through electrode is a cavity.
   (2)

The imaging element according to (1), in which
the pad and the through electrode are disposed at positions at which there is no region where the opening of the pad and the opening of the through electrode adjacent to the pad overlap in plan view.
   (3)

The imaging element according to (1) or (2), in which
the pad and the through electrode are disposed such that a central axis of the pad and a central axis of the through electrode adjacent to the pad are located at positions shifted from each other in cross-sectional view.
   (4)

The imaging element according to any of (1) to (3), in which
the pad is a pad used for probe measurement.
   (5)

The imaging element according to any of (1) to (4), in which
the rewiring layer includes a rewiring line, a solder mask covering the rewiring line, and a land connected to the rewiring line and exposed from the solder mask,
a front surface of the solder mask and a surface of the land are provided to be flush with each other, and
the rewiring layer electrically connects the through electrode and the land with each other.
   (6)

The imaging element according to any of (1) to (5), in which
the pad's side of the through electrode is filled with an organic material, silicon oxide, or a material having a hardness similar to that of silicon oxide with a predetermined thickness.
   (7)

The imaging element according to any of (1) to (6), in which
at least one side of a side wall of the pad has an uneven shape.
   (8)

The imaging element according to any of (1) to (7), in which
at least one side of a side wall of the pad is opened. (9)

The imaging element according to any of (1) to (8), further including:
a glass substrate covering at least the pixel array unit and disposed on a light incident surface side; and
a base provided between the glass substrate and the first surface,
in which
the base is disposed at a position at which there is no region overlapping with the opening of the pad.
   (10)

The imaging element according to any of (1) to (9), further including:
a glass substrate disposed on a light incident surface side; and
a base provided between the glass substrate and the first surface,
in which
the glass substrate and the base each include a through hole at a position overlapping the opening of the pad, the through hole having a size similar to the opening of the pad.
   (11)

The imaging element according to any of (1) to (10), further including:
a lens barrel; and
a base that bonds the lens barrel and the first surface together,
in which
a part of the base is formed in the pad.
   (12)

The imaging element according to any of (1) to (11), further including
a wiring line connected to the electrode and partially exposed.
   (13)

The imaging element according to (12), further including:
a glass substrate disposed on a light incident surface side; and
a bonding resin provided between the glass substrate and the first surface and bonding the glass substrate,
in which
the wiring line has unevenness on a surface in contact with the bonding resin.
   (14)

The imaging element according to claim 12, further including:
a glass substrate disposed on a light incident surface side; and
a base provided between the glass substrate and the first surface,
in which
the wiring line is included in the base.
   (15)

The imaging element according to (1), further including
a fuse on a part of a wiring line connecting the electrode and a circuit in the imaging element to each other.
   (16)

An imaging element including:
a pixel array unit in which pixels each including a photoelectric conversion element are two-dimensionally arranged;
a wiring line connected to a circuit that processes a signal from the pixel array unit and exposed on a side surface of the imaging element; and
a fuse provided on a part of the wiring line.
   (17)

The imaging element according to (16), further including:
an electrode provided in a state of being exposed to the bottom of a pad including an opening on a side of a first surface on which the pixel array unit is provided and connected to the wiring line;
a through electrode including an opening on a second surface on an opposite side from the first surface; and
a rewiring layer stacked on the second surface,
in which
the inside of the through electrode is a cavity.
   (18)

The imaging element according to (16) or (17), in which the fuse electrically disconnects the wiring line and the circuit from each other.

(19)

An electronic device including:
an imaging element including:
a pixel array unit in which pixels each including a photoelectric conversion element are two-dimensionally arranged;
a pad including an opening on a side of a first surface on which the pixel array unit is provided;
an electrode provided in a state of being exposed to the bottom of the pad;
a through electrode including an opening on a second surface on an opposite side from the first surface; and
a rewiring layer stacked on the second surface,
in which
the inside of the through electrode is a cavity; and
a processing unit that processes a signal from the imaging element.

### REFERENCE SIGNS LIST

1 Imaging element
2 Pixel
3 Pixel array unit
4 Vertical drive circuit
5 Column signal processing circuit
6 Horizontal drive circuit
7 Output circuit
8 Control circuit
9 Vertical signal line
10 Horizontal signal line
11 Semiconductor substrate
12 Input/output terminal
21 Photodiode
22 Transfer transistor
23 Floating diffusion
24 Reset transistor
25 Amplification transistor
26 Selection transistor
51 Pad
52 Electrode
70 Rewiring layer
71 Support substrate
72 Insulating film
73 Barrier metal
74 Rewiring line
75 Solder resist
76 Through electrode
80 Semiconductor substrate
81 Wiring layer
82 Color filter
83 On-chip lens
111 Adhesive layer
112 Temporary substrate
113 Dicing ring
211 Reinforcing film
221 Reinforcing film
251 Base
252 Glass substrate
261 Base
262 Glass substrate
311 Base
312 Lens barrel

1. An imaging element comprising:
a pixel array unit in which pixels each including a photoelectric conversion element are two-dimensionally arranged;
a pad including an opening on a side of a first surface on which the pixel array unit is provided;
an electrode provided in a state of being exposed to a bottom of the pad;
a through electrode including an opening on a second surface on an opposite side from the first surface; and
a rewiring layer stacked on the second surface,
wherein
an inside of the through electrode is a cavity.

2. The imaging element according to claim 1, wherein
the pad and the through electrode are disposed at positions at which there is no region where the opening of the pad and the opening of the through electrode adjacent to the pad overlap in plan view.

3. The imaging element according to claim 1, wherein
the pad and the through electrode are disposed such that a central axis of the pad and a central axis of the through electrode adjacent to the pad are located at positions shifted from each other in cross-sectional view.

4. The imaging element according to claim 1, wherein
the pad is a pad used for probe measurement.

5. The imaging element according to claim 1, wherein
the rewiring layer includes a rewiring line, a solder mask covering the rewiring line, and a land connected to the rewiring line and exposed from the solder mask,
a front surface of the solder mask and a surface of the land are provided to be flush with each other, and
the rewiring layer electrically connects the through electrode and the land with each other.

6. The imaging element according to claim 1, wherein
the pad's side of the through electrode is filled with an organic material, silicon oxide, or a material having a hardness similar to that of silicon oxide with a predetermined thickness.

7. The imaging element according to claim 1, wherein
at least one side of a side wall of the pad has an uneven shape.

8. The imaging element according to claim 1, wherein
at least one side of a side wall of the pad is opened.

9. The imaging element according to claim 1, further comprising:
a glass substrate covering at least the pixel array unit and disposed on a light incident surface side; and
a base provided between the glass substrate and the first surface,
wherein
the base is disposed at a position at which there is no region overlapping with the opening of the pad.

10. The imaging element according to claim 1, further comprising:
a glass substrate disposed on a light incident surface side; and
a base provided between the glass substrate and the first surface,
wherein
the glass substrate and the base each include a through hole at a position overlapping the opening of the pad, the through hole having a size similar to the opening of the pad.

11. The imaging element according to claim 1, further comprising:
a lens barrel; and
a base that bonds the lens barrel and the first surface together,
wherein
a part of the base is formed in the pad.

12. The imaging element according to claim 1, further comprising
a wiring line connected to the electrode and partially exposed.

13. The imaging element according to claim 12, further comprising:
a glass substrate disposed on a light incident surface side; and
a bonding resin provided between the glass substrate and
the first surface and bonding the glass substrate, wherein
the wiring line has unevenness on a surface in contact with the bonding resin.

14. The imaging element according to claim 12, further comprising:
a glass substrate disposed on a light incident surface side; and
a base provided between the glass substrate and the first surface,
wherein
the wiring line is included in the base.

15. The imaging element according to claim 1, further comprising
a fuse on a part of a wiring line connecting the electrode and a circuit in the imaging element to each other.

16. An imaging element comprising:
a pixel array unit in which pixels each including a photoelectric conversion element are two-dimensionally arranged;
a wiring line connected to a circuit that processes a signal from the pixel array unit and exposed on a side surface of the imaging element; and
a fuse provided on a part of the wiring line.

17. The imaging element according to claim 16, further comprising:
an electrode provided in a state of being exposed to a bottom of a pad including an opening on a side of a first surface on which the pixel array unit is provided and connected to the wiring line;
a through electrode including an opening on a second surface on an opposite side from the first surface; and
a rewiring layer stacked on the second surface,
wherein
an inside of the through electrode is a cavity.

18. The imaging element according to claim 16, wherein the fuse electrically disconnects the wiring line and the circuit from each other.

19. An electronic device comprising:
an imaging element including:
a pixel array unit in which pixels each including a photoelectric conversion element are two-dimensionally arranged;
a pad including an opening on a side of a first surface on which the pixel array unit is provided;
an electrode provided in a state of being exposed to a bottom of the pad;
a through electrode including an opening on a second surface on an opposite side from the first surface; and
a rewiring layer stacked on the second surface,
wherein
an inside of the through electrode is a cavity; and
a processing unit that processes a signal from the imaging element.
